(19) United States
(12) Patent Application Publication
(10) Pub. No.: US 2018/0019054 A1
(43) Pub. Date: Jan. 18, 2018

(54) INDUCTOR ELEMENT, COIL ANTENNA, ANTENNA DEVICE, CARD INFORMATION MEDIUM, AND ELECTRONIC DEVICE

(71) Applicant: Murata Manufacturing Co., Ltd., Nagaokakyo-shi (JP)

(72) Inventor: Nobuyuki TENNO, Nagaokakyo-shi (JP)

(21) Appl. No.: 15/717,984

(22) Filed: Sep. 28, 2017

Related U.S. Application Data
(63) Continuation of application No. PCT/JP2016/058236, filed on Mar. 16, 2016.

(30) Foreign Application Priority Data
Apr. 9, 2015 (JP) 2015-079957

(51) Int. Cl. H01F 27/28; G06K 19/077; H01F 27/29; H05K 1/18; H01F 38/14; H01Q 7/00; H01Q 1/24

(52) U.S. Cl. CPC H01F 27/2804; H01F 27/292; G06K 19/07783; H01Q 1/243; H01F 38/14; H02J 50/10; G06K 19/07722; G06K 19/07735; G06K 19/07732; H01Q 7/00; H05K 1/181

(57) ABSTRACT

A coil antenna includes an insulator with a first principal surface and a second principal surface opposing to the first principal surface, a coil conductor provided on or in the insulator, a first pad electrode and a second pad electrode both provided on the first principal surface, and a third pad electrode and a fourth pad electrode both provided on the second principal surface. The coil conductor includes a first end and a second end. The first pad electrode and the third pad electrode are electrically connected to the first end side of the coil conductor, while the second pad electrode and the fourth pad electrode are electrically connected to the second end side of the coil conductor. Thus, the pad electrodes connected to the coil conductor are provided on each of the first principal surface and the second principal surface of the insulator.

### CROSS REFERENCE TO RELATED APPLICATIONS

This application claims the benefit of priority to Japanese Patent Application No. 2015-079957 filed on Apr. 9, 2015 and is a Continuation application of PCT Application No. PCT/JP2016/058236 filed on Mar. 16, 2016. The entire contents of each application are hereby incorporated herein by reference.

### BACKGROUND OF THE INVENTION

### 1. Field of the Invention

The present invention relates to an inductor element, and more particularly to an inductor element including an insulator and mounting terminals, the mounting terminals being provided at two principal surfaces of the insulator. The present invention further relates to a coil antenna, and more particularly to a coil antenna including an insulator and mounting terminals, the mounting terminals being provided at two principal surfaces of the insulator. The present invention still further relates to an antenna device including the coil antenna and a planar conductor. The present invention still further relates to a card information medium including the coil antenna. The present invention still further relates to an electronic device including at least one of the above-mentioned components.

### 2. Description of the Related Art

It has been known so far that, in a multilayer inductor element, a multilayer body warps during firing due to residual stress caused by the difference in thermal expansion coefficient between a material of a mounting electrode and a material of the multilayer body. Japanese Unexamined Patent Application Publication No. 2014-207432 discloses a multilayer inductor element aiming to suppress the warpage of the multilayer body, which is generated during the firing.

The multilayer inductor element disclosed in Japanese Unexamined Patent Application Publication No. 2014-207432 includes a multilayer body and pad electrodes serving as mounting electrodes. The warpage of the multilayer body generated during the firing due to the residual stress can be suppressed by forming the pad electrodes on both principal surfaces of the multilayer body. Accordingly, flatness of the inductor element can be ensured and the inductor element having a smaller thickness can be realized with the above-described configuration.

With recent progress toward further reduction in size and further sophistication in functions of electronic devices, it has become difficult to secure, in a casing of the electronic device, a sufficient space where an antenna, an inductor element, etc. are arranged. Thus, the antenna, the inductor element, etc., each mounted inside the casing of the electronic device, are often required to be adaptable for various connection methods.

With the configuration disclosed in Japanese Unexamined Patent Application Publication No. 2014-207432, however, because the pad electrodes connected to the inductor are provided only at a mounting surface, various connection methods cannot be adaptively utilized, and a degree of freedom in design of layout of the inductor element, for example, is reduced.

### SUMMARY OF THE INVENTION

Preferred embodiments of the present invention provide inductor elements, coil antennas, and antenna devices, which are adaptable for various connection methods with simple configurations, as well as card information media and electronic devices each of which includes at least one of the above-mentioned components.

An inductor element according to a preferred embodiment of the present invention includes: an insulator that includes a first principal surface and a second principal surface opposing to the first principal surface; a coil conductor that is provided on or in the insulator, that has a winding axis, and that includes a first end and a second end; a first pad electrode that is provided at the first principal surface, and that is electrically connected to a side including the first end; a second pad electrode that is provided at the first principal surface, and that is electrically connected to a side including the second end; a third pad electrode that is provided at the second principal surface, and that is electrically connected to the first end side; and a fourth pad electrode that is provided at the second principal surface, and that is electrically connected to the second end side, wherein the first pad electrode, the second pad electrode, the third pad electrode, and the fourth pad electrode are independent of one another.

With the features described above, the first pad electrode and the second pad electrode are each electrically connected to the first end side of a coil conductor, which is provided on or in the insulator, and are provided at the first principal surface of the insulator. Furthermore, the third pad electrode and the fourth pad electrode are each electrically connected to the second end side of the coil conductor, and are provided at the second principal surface of the insulator. Thus, since the pad electrodes connected to the coil conductor are provided at each of the first principal surface and the second principal surface of the insulator, an inductor element which is adaptable for various connection methods is able to be realized.

Preferably, the first pad electrode and the third pad electrode are electrically connected at positions inside the insulator. With this feature, since connected portions of the first pad electrode and the third pad electrode are protected by the insulator, the inductor element is robust in its entirety. Moreover, reliability of the connected portions of the first pad electrode and the third pad electrode is high.

Preferably, the second pad electrode and the fourth pad electrode are electrically connected at positions inside the insulator. With this feature, since connected portions of the second pad electrode and the fourth pad electrode are protected by the insulator, the inductor element is robust in its entirety. Moreover, reliability of the connected portions of the second pad electrode and the fourth pad electrode is high.

The first principal surface preferably includes a first side and a second side perpendicular to the first side, and the insulator is a rectangular parallelepiped having a third side that is perpendicular to the first side and the second side.

The first pad electrode and the third pad electrode preferably are rotationally symmetrical about a first axis that passes a center of the insulator and that is parallel to the first side, and the second pad electrode and the fourth pad electrode preferably are rotationally symmetrical about the first axis that passes the center of the insulator, and that is parallel to the first side. With these features, even when the inductor element is rotated by 180° with respect to the first axis, the pad electrodes electrically connected to the coil conductor remain in the same positional relationship relative to one another. Therefore, when the inductor element is mounted to a printed wiring board, for example, each of the first principal surface and the second principal surface is able to be optionally utilized as a mounting surface.

Preferably, the first pad electrode and the fourth pad electrode are rotationally symmetrical about a second axis that passes a center of the insulator, and that is parallel to the second side, and the second pad electrode and the third pad electrode are rotationally symmetrical about the second axis that passes the center of the insulator, and that is parallel to the second side. With those features, even when the inductor element is rotated by 180° with respect to the second axis, the pad electrodes electrically connected to the coil conductor remain in the same positional relationship relative to one another. Therefore, when the inductor element is mounted to a printed wiring board, for example, each of the first principal surface and the second principal surface is able to be each optionally utilized as a mounting surface.

Preferably, the first pad electrode and the second pad electrode are rotationally symmetrical about a third axis that passes a center of the insulator, and that is parallel to the third side, and the third pad electrode and the fourth pad electrode are rotationally symmetrical about the third axis that passes the center of the insulator, and that is parallel to the third side. With these features, even when the inductor element is rotated by 360°/n with respect to the third axis, the pad electrodes electrically connected to the coil conductor remain in the same positional relationship relative to one another. Therefore, the inductor element adaptable for various connection methods is realized.

A direction in which the first pad electrode and the second pad electrode are arrayed may be non-parallel to the first side and non-parallel to the second side, and a direction in which the third pad electrode and the fourth pad electrode are arrayed may be non-parallel to the first side and non-parallel to the second side.

Preferably, the inductor element further includes a first connection conductor that electrically connects the first pad electrode and the first end side, a second connection conductor that electrically connects the second pad electrode and the second end side, a third connection conductor that electrically connects the third pad electrode and the first end side, and a fourth connection conductor that electrically connects the fourth pad electrode and the second end side, wherein the first pad electrode, the second pad electrode, the third pad electrode, the fourth pad electrode, the first connection conductor, the second connection conductor, the third connection conductor, and the fourth connection conductor are arranged outside a coil aperture of the coil conductor when viewed from a direction of the winding axis of the coil conductor.

With the features described above, any pad electrodes and any connection conductors are not arranged within the coil aperture of the coil conductor when viewed from the direction of the winding axis. Thus, an inductor element having stable inductance components is able to be realized because, not only are the connection conductors electrically connecting the individual pad electrodes and the coil conductor, but the individual pad electrodes also do not interfere with the coil aperture of the coil conductor.

A coil antenna according to a preferred embodiment of the present invention includes: an insulator that includes a first principal surface and a second principal surface opposing to the first principal surface; a coil conductor that is provided on or in the insulator, that has a winding axis, and that includes a first end and a second end; a first pad electrode that is provided at the first principal surface, and that is electrically connected to a side including the first end; a second pad electrode that is provided at the first principal surface, and that is electrically connected to a side including the second end; a third pad electrode that is provided at the second principal surface, and that is electrically connected to the first end side; and a fourth pad electrode that is provided at the second principal surface, and that is electrically connected to the second end side, wherein the first pad electrode, the second pad electrode, the third pad electrode, and the fourth pad electrode are independent of one another.

With the features described above, the first pad electrode and the second pad electrode each electrically connected to the first end side of a coil conductor, which is provided on or in the insulator, are at the first principal surface of the insulator. Furthermore, the third pad electrode and the fourth pad electrode each electrically connected to the second end side of the coil conductor are provided at the second principal surface of the insulator. Thus, since the pad electrodes connected to the coil conductor are provided at each of the first principal surface and the second principal surface, an inductor element adaptable for various connection methods is realized.

Preferably, the coil antenna further includes a first connection conductor that electrically connects the first pad electrode and the first end side, a second connection conductor that electrically connects the second pad electrode and the second end side, a third connection conductor that electrically connects the third pad electrode and the first end side, and a fourth connection conductor that electrically connects the fourth pad electrode and the second end side, wherein the first pad electrode, the second pad electrode, the third pad electrode, the fourth pad electrode, the first connection conductor, the second connection conductor, the third connection conductor, and the fourth connection conductor are located outside a coil aperture of the coil conductor when viewed from a direction of the winding axis of the coil conductor.

With the features described above, any pad electrodes and any connection conductors are not located within the coil aperture of the coil conductor when viewed from the direction of the winding axis. Thus, since not only the connection conductors electrically connecting the individual pad electrodes and the coil conductor, but also the individual pad electrodes do not interfere with the coil aperture of the coil conductor, the coil antenna is able to more easily establish coupling to an antenna coil on the communication counterpart side. As a result, a coil antenna having good communication characteristics is able to be realized.

Preferably, the first principal surface includes a first side and a second side perpendicular to the first side, the insulator is a rectangular parallelepiped including a third side that is perpendicular to the first side and the second side, and the winding axis of the coil conductor is parallel to one of the first side, the second side, and the third side. With these features, even when the coil antenna is rotated by 180° about an axis that is parallel to one of the first side, the second side, and the third side, magnetic-flux radiation characteristics of the coil antenna are not changed from those before the rotation because the direction of the winding axis the coil conductor is not changed.

An antenna device according to a preferred embodiment of the present invention includes: a coil antenna according to a preferred embodiment of the present invention described above; and a planar conductor that is positioned close to or adjacent to the first pad electrode and the second pad electrode, or to the coil conductor, wherein the third pad electrode and the fourth pad electrode are electrically conducted to a power feed circuit, and the planar conductor is coupled to the first pad electrode and the second pad electrode, or to the coil conductor through an electric field, a magnetic field, or an electromagnetic field.

With the features described above, since the planar conductor is coupled to the first pad electrode and the second pad electrode or to the coil conductor through an electric field, a magnetic field, or an electromagnetic field, the planar conductor functions as a booster antenna of the coil antenna. In comparison with the case of including only the coil antenna, therefore, an effective coil aperture substantially defining and functioning as an antenna is increased, and magnetic flux is able to be radiated (or collected) over a wider range and a longer distance. This makes it easier to establish coupling to an antenna coil on the communication counterpart side. As a result, a coil antenna having good communication characteristics is able to be realized with a simple configuration without using a large-sized antenna coil.

A card information medium according to a preferred embodiment of the present invention includes the inductor element according to any one of the above-described preferred embodiments of the present invention.

A card information medium according to a preferred embodiment of the present invention includes the coil antenna according to any one of the above-described preferred embodiments of the present invention.

An electronic device according to a preferred embodiment of the present invention includes the inductor element according to any one of the above-described preferred embodiments of the present invention, the coil antenna according to any one of the above-described preferred embodiments of the present invention, or the card information medium according to any one of the above-described preferred embodiments of the present invention, and a casing, wherein the inductor element, the coil antenna, or the card information medium is accommodated in the casing.

With the features described above, an electronic device including the inductor element, the coil antenna used in a communication system in a HF band or a UFH band, and the card information medium is able to be realized.

An electronic device according to a preferred embodiment of the present invention includes the antenna device according to any one of the above-described preferred embodiments of the present invention, and a casing, wherein the planar conductor is a portion or the entirety of the casing of the electronic device. With those features, the planar conductor is able to be easily provided by utilizing a portion or the entirety of the casing. Thus, it is not necessary to separately form the planar conductor, manufacturing of the electronic device is relatively easy and cost reduction is realized.

An electronic device according to a preferred embodiment of the present invention includes: the card information medium according to any one of the above-described preferred embodiments of the present invention; a card loading assembly into which the card information medium is removably inserted; and a casing, wherein the card information medium and the card loading assembly are accommodated in the casing, the third pad electrode and the fourth pad electrode are electrically conducted to a power feed circuit, and the card loading assembly is positioned close to or adjacent to the first pad electrode and the second pad electrode, or to the coil conductor, and is coupled to the first pad electrode and the second pad electrode, or to the coil conductor through an electric field, a magnetic field, or an electromagnetic field.

With the features described above, since the card loading assembly is coupled to the first pad electrode and the second pad electrode or to the coil conductor through an electric field, a magnetic field, or an electromagnetic field, the card loading assembly defines and functions as a booster antenna of the coil antenna. As a result, the electronic device is able to be realized in which the card loading assembly does not impede passage of magnetic flux, and in which the coil antenna included in the card information medium is able to strongly couple to another coil antenna on the communication counterpart side.

According to preferred embodiments of the present invention, it is possible to provide inductor elements, coil antennas, and antenna devices, which are adaptable for various connection methods with simple configurations, as well as card information media and electronic devices each of which includes at least one of the above-described components.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1A is an external perspective view of a coil antenna 101 according to a first preferred embodiment of the present invention, and FIG. 1B is a left side view of the coil antenna 101.

FIG. 2A is a plan view of the coil antenna 101, FIG. 2B is a front view of the coil antenna 101, and FIG. 2C is a bottom view of the coil antenna 101.

FIG. 3 is an exploded plan view illustrating electrode patterns, etc. on individual base material layers of the coil antenna 101.

FIG. 4 is a circuit diagram of the coil antenna 101 according to the first preferred embodiment of the present invention.

FIG. 5A is a sectional view illustrating the coil antenna 101 in a state mounted using a first connection method, FIG. 5B is a sectional view illustrating the coil antenna 101 in a state mounted using a second connection method, FIG. 5C is a sectional view illustrating the coil antenna 101 in a state mounted using a third connection method, and FIG. 5D is a sectional view illustrating the coil antenna 101 in a state mounted using a fourth connection method.

FIG. 6 is a detailed sectional view of an antenna device including the coil antenna 101 according to the first preferred embodiment of the present invention and a planar conductor 7.

FIG. 7 is an external perspective view of a coil antenna 102 according to a second preferred embodiment of the present invention.

FIG. 8A is a plan view of a coil antenna 103 according to a third preferred embodiment of the present invention, FIG. 8B is a front view of the coil antenna 103, and FIG. 8C is a bottom view of the coil antenna 103.

FIG. 9A is a plan view of a coil antenna 104 according to a fourth preferred embodiment of the present invention, FIG. 9B is a front view of the coil antenna 104, and FIG. 9C is a bottom view of the coil antenna 104.

FIG. 10A is a plan view of a coil antenna 105 according to a fifth preferred embodiment of the present invention, and FIG. 10B is a bottom view of the coil antenna 105.

FIG. 11A is a plan view of a coil antenna 106A according to a sixth preferred embodiment of the present invention, and FIG. 11B is a bottom view of the coil antenna 106A.

FIG. 12A is a plan view of a coil antenna 106B according to the sixth preferred embodiment of the present invention, and FIG. 12B is a bottom view of the coil antenna 106B.

FIG. 13A is a circuit diagram of a coil antenna 107A according to a seventh preferred embodiment of the present invention, FIG. 13B is a circuit diagram of a coil antenna 107B, and FIG. 13C is a circuit diagram of a coil antenna 107C.

FIG. 14 is an exploded plan view illustrating electrode patterns, etc. on individual base material layers of a coil antenna 108A according to an eighth preferred embodiment of the present invention.

FIG. 15 is a circuit diagram of the coil antenna 108A.

FIG. 16A is a circuit diagram of a coil antenna 108B, and FIG. 16B is a circuit diagram of a coil antenna 108C.

FIG. 17A is a circuit diagram of a coil antenna 109A according to a ninth preferred embodiment of the present invention, FIG. 17B is a circuit diagram of a coil antenna 109B, and FIG. 17C is a circuit diagram of a coil antenna 109C.

FIG. 18A is a plan view of a coil antenna 110 according to a tenth preferred embodiment of the present invention, FIG. 18B is a front view of the coil antenna 110, and FIG. 18C is a bottom view of the coil antenna 110.

FIG. 19 is a circuit diagram of the coil antenna 110.

FIG. 20 is an external perspective view of an electronic device 301 according to an eleventh preferred embodiment of the present invention.

FIG. 21 is a partial sectional view of the electronic device 301, the view illustrating a path of interlinkage magnetic flux with respect to the coil antenna 101 mounted on a wiring board 70.

FIG. 22 is a circuit diagram of a communication circuit in the electronic device 301.

FIG. 23A is an external perspective view of an electronic device 302 according to a twelfth preferred embodiment of the present invention, and FIG. 23B is a plan view of a card information medium 201 according to the twelfth preferred embodiment of the present invention.

FIG. 24A is an external perspective view of an electronic device 303 according to a thirteenth preferred embodiment of the present invention, and FIG. 24B is a plan view of a card information medium 202 according to the thirteenth preferred embodiment of the present invention.

FIG. 25A is a perspective view of a portion of a wiring board 70 where a slot case 73 is mounted to the wiring board 70, FIG. 25B illustrates a shape of a coil conductor ANT, and FIG. 25C illustrates a relationship between the slot case 73 and the coil conductor ANT in a plan view.

FIG. 26 is a plan view illustrating a structure inside a casing of an electronic device according to a fourteenth preferred embodiment of the present invention.

FIG. 27 is a perspective view of a booster antenna 120.

FIG. 28 is a circuit diagram of the booster antenna 120.

### DETAILED DESCRIPTION OF THE PREFERRED EMBODIMENTS

A plurality of preferred embodiments of the present invention will be described below in relation to several practical examples by referring to the drawings. In the drawings, the same members and portions are denoted by the same reference signs. It is to be noted that the following preferred embodiments are merely illustrative, and that configurations disclosed in different preferred embodiments may be partially replaced or combined with each other.

Coil antennas according to several preferred embodiments described below are each a coil antenna that can be disposed in an electronic device such as represented by a cellular phone terminal (including a smartphone), and that can be used, for example, as a magnetic-flux radiation element in an HF band. The coil antennas can also be used as inductor elements. Thus, several preferred embodiments described below represent non-limiting examples of both the coil antenna and the inductor element unless otherwise specified.

In the following preferred embodiments, the term “antenna device” preferably is an antenna that radiates magnetic flux. More specifically, the antenna device preferably is an antenna that communicates with a counterpart antenna in near fields through magnetic field coupling, and it is utilized, for example, in NFC (Near field communication). A frequency band used by the antenna device is, for example, an HF band. In particular, a frequency of 13.56 MHz or near 13.56 MHz is preferably used, for example. The size of the antenna device is much smaller than a wavelength λ at the used frequency, and electromagnetic-wave radiation characteristics in a used frequency band is poor. The antenna device preferably has a length of not more than about λ/10 in a state where a coil conductor disposed in the antenna device is extended into a straight structure. The term “wavelength” indicates an effective wavelength in consideration of a wavelength contraction effect attributable to dielectric property and permeability of a base material of an antenna.

### First Preferred Embodiment

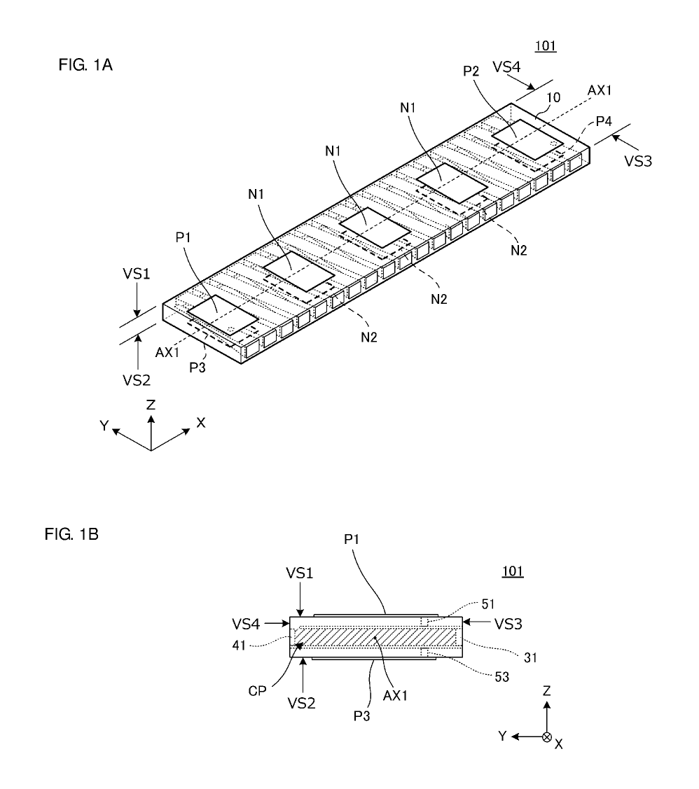

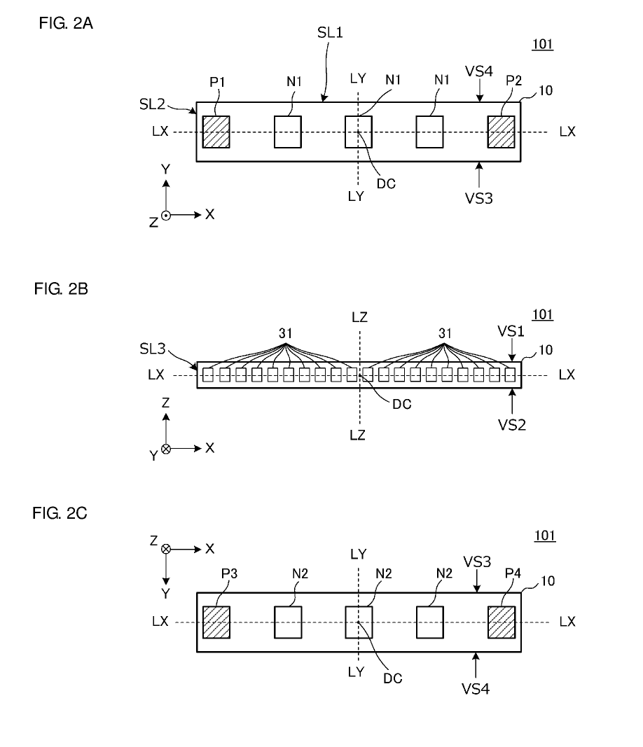

FIG. 1A is an external perspective view of a coil antenna 101 according to a first preferred embodiment, and FIG. 1B is a left side view of the coil antenna 101. FIG. 2A is a plan view of the coil antenna 101, FIG. 2B is a front view of the coil antenna 101, and FIG. 2C is a bottom view of the coil antenna 101.

In FIGS. 2A and 2C, for easier understanding of structure, a first pad electrode P1, a second pad electrode P2, a third pad electrode P3, and a fourth pad electrode P4 are denoted by hatching. This illustration by hatching is similarly applied to plan views and bottom views representing the preferred embodiments of the present invention described below.

The coil antenna 101 includes an insulator 10, a coil conductor (described in detail later) provided on or in the insulator 10, the first pad electrode P1, the second pad electrode P2, the third pad electrode P3, the fourth pad electrode P4, and dummy electrodes N1 and N2.

The insulator 10 is a multilayer body preferably having a rectangular or substantially rectangular parallelepiped shape in which a lengthwise direction is aligned with a horizontal direction (X direction in FIG. 2A). The insulator 10 includes a first principal surface VS1 and a second principal surface VS2 that are opposed to each other in a thickness direction (Z direction), and further includes a first lateral surface VS3 and a second lateral surface VS4 that are positioned in a spaced relationship in a vertical direction (Y direction).

As illustrated in FIG. 2A, the first principal surface VS1 preferably includes a first side SL1 and a second side SL2 perpendicular to the first side SL1. The first side SL1 is parallel to the X direction, and the second side SL2 is parallel to the Y direction. Furthermore, as illustrated in FIG. 2B, the insulator 10 preferably includes a third side SL3 that is perpendicular to the first side SL1 and the second side SL2, and that is parallel to the Z direction.

As illustrated in FIG. 2, first connection conductors 31 are provided at the first lateral surface VS3 of the insulator 10, and second connection conductors 41 are provided at the second lateral surface VS4 of the insulator 10. The first connection conductors 31 are each a conductor pattern extending in the thickness direction (Z direction), and twenty conductor patterns are arrayed side by side along the lengthwise direction (X direction) of the insulator 10. The second connection conductors are each a conductor pattern extending in the thickness direction (Z direction), and nineteen conductor patterns, for example, are preferably arrayed side by side along the lengthwise direction (X direction) of the insulator 10. The first connection conductors 31 and the second connection conductors 41 can be formed, for example, by providing a mother substrate including a plurality of via conductors arrayed side by side along a first direction, and then separating (cutting) the mother substrate along the first direction such that each via conductor having a cylindrical shape is divided into two conductors each having a semi-cylindrical shape.

The first pad electrode P1, the second pad electrode P2, and the dummy electrodes N1 are provided at the first principal surface VS1 of the insulator 10. The first pad electrode P1 and the second pad electrode P2 are each a conductor pattern having a rectangular or substantially rectangular shape in a plan view, and they are arranged near both end portions of the insulator 10 in the lengthwise direction (X direction). The dummy electrodes N1 are each a conductor pattern having a rectangular or substantially rectangular shape in a plan view, and three dummy electrodes are arranged side by side along the lengthwise direction (X direction) of the insulator 10 between the first pad electrode P1 and the second pad electrode P2. The first pad electrode P1, the second pad electrode P2, and the dummy electrodes N1 are each a metal film containing Cu, Ni or Au, for example, as a main ingredient.

The third pad electrode P3, the fourth pad electrode P4, and the dummy electrodes N2 are preferably provided at the second principal surface VS2 of the insulator 10. The third pad electrode P3 and the fourth pad electrode P4 are each a conductor pattern having a rectangular or substantially rectangular shape in a plan view, and they are arranged near both the end portions of the insulator 10 in the lengthwise direction (X direction). The dummy electrodes N2 are each a conductor pattern having a rectangular or substantially rectangular shape in a plan view, and three dummy electrodes are arranged side by side along the lengthwise direction (X direction) of the insulator 10 between the third pad electrode P3 and the fourth pad electrode P4. The third pad electrode P3, the fourth pad electrode P4, and the dummy electrodes N2 are each a metal film containing Cu, Ni or Au, for example, as a main ingredient.

The first pad electrode P1, the second pad electrode P2, the third pad electrode P3, and the fourth pad electrode P4 are conductor patterns that are independent from one another. In descriptions of preferred embodiments of the present invention, the conductor patterns being “independent from one another” indicates conductor patterns that are electrically connected to different contacts when mounted. In an example, terminal electrodes provided on five surfaces of each of end portions of a chip inductor having a rectangular or substantially rectangular parallelepiped shape are not the conductor patterns being “independent from one another” because those terminal electrodes on all the surfaces are electrically connected to one contact with formation of a fillet of a conductive joining material when the chip inductor is mounted. Thus, the conductor patterns being “independent from one another” are discriminated from the terminal electrodes of the related-art chip inductor, etc. The above-mentioned point is similarly applied to the following preferred embodiments of the present invention.

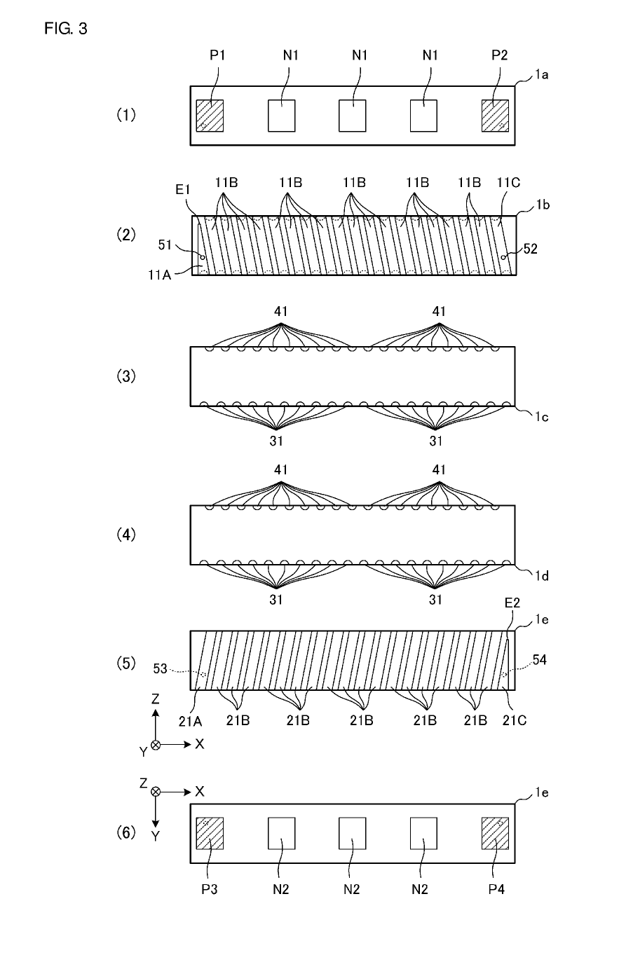

A structure of the insulator 10 will be described below. FIG. 3 is an exploded plan view illustrating electrode patterns, etc. on individual base material layers of the coil antenna 101.

The insulator 10 is preferably defined by successively laminating a plurality of base material layers 1a, 1b, 1c, 1d and 1e, denoted by (1) to (6) in FIG. 3, in the mentioned order. In FIG. 3, (1) denotes an uppermost layer, while (5) and (6) denote a lowermost layer. Additionally, in FIG. 3, (6) denotes a rear surface on the opposite side to (5).

The base material layers 1a and 1e are each nonmagnetic layers having a rectangular or substantially rectangular parallelepiped shape, and the base material layers 1b, 1c and 1d are each magnetic layers having a rectangular or substantially rectangular parallelepiped shape. The base material layers 1a and 1e are made of nonmagnetic ferrite, for example, and the base material layers 1b, 1c and 1d are made of magnetic ferrite, for example. In other words, the insulator 10 has a configuration that the base material layers 1b, 1c and 1d as magnetic layers are sandwiched between the base material layers 1a and 1e as the nonmagnetic layers.

The first pad electrode P1, the second pad electrode P2, and the dummy electrodes N1 are provided at one principal surface (front surface in FIG. 3) of the base material layer 1a denoted by (1). The first pad electrode P1 and the second pad electrode P2 are each a conductor pattern having a rectangular or substantially rectangular shape in a plan view, and those electrodes are arranged near both end portions of the base material layer 1a in a lengthwise direction thereof. The dummy electrodes N1 are each a conductor pattern having a rectangular or substantially rectangular shape in a plan view, and three dummy electrodes N1 are arranged side by side along the lengthwise direction (X direction) of the base material layer 1a between the first pad electrode P1 and the second pad electrode P2. In other words, the first pad electrode P1, the three dummy electrodes N1, and the second pad electrode P2 are successively arranged, as illustrated in FIG. 2, along the lengthwise direction of the base material layer 1a.

First linear conductors 11A, 11B and 11C are provided at one principal surface (front surface in FIG. 3) of the base material layer 1b denoted by (2). The first linear conductors 11A, 11B and 11C are each a conductor pattern that is preferably formed, for example, by providing a conductor film, such as a Cu film, at the one principal surface of the base material layer 1b with a plating process, for example, and by patterning the conductor film with photolithography. Alternatively, the first linear conductors 11A, 11B and 11C may be formed by screen printing of a conductive paste, for example.

The first linear conductor 11A is preferably a conductor pattern having a trapezoidal or substantially trapezoidal shape in a plan view. The trapezoidal conductor pattern includes a lower base facing (reaching) side of the base material layer 1b in a widthwise direction thereof (i.e., a lower side of the base material layer 1b in FIG. 3), and an upper base defining an end portion E1. Thus, the conductor pattern of the first linear conductor 11A has a tapered shape gradually thinning from the one side of the base material layer 1b in the widthwise direction (i.e., from the lower side of the base material layer 1b in FIG. 3) toward the other side (i.e., an upper side of the base material layer 1b in FIG. 3). The first linear conductor 11A is arranged near one side of the base material layer 1b in a lengthwise direction thereof (i.e., a left side of the base material layer 1b in FIG. 3). Because of the tapered shape of the first linear conductor 11A that is arranged on the outermost side of a later-described coil conductor along a direction of a winding axis AX1 of the coil conductor (i.e., along the X direction), an increase in volume of the coil antenna 101 is significantly reduced or prevented while the number of windings of the coil conductor is increased.

The first linear conductors 11B and 11C are each a conductor pattern having a parallelogram shape in a plan view, and the electrodes extend from the one side of the base material layer 1b in the widthwise direction (i.e., from the lower side of the base material layer 1b in FIG. 3) toward the other side (i.e., the upper side of the base material layer 1b in FIG. 3). Preferably, a plurality of the first linear conductors 11B, i.e., eighteen, are arranged side by side along the lengthwise direction of the base material layer 1b. The first linear conductor 11C is arranged near the other side of the base material layer 1b in the lengthwise direction (i.e., a right side of the base material layer 1b in FIG. 3). In other words, the first linear conductor 11A, the eighteen first linear conductors 11B, and the first linear conductor 11C are successively arranged along the lengthwise direction of the base material layer 1b, as illustrated in FIG. 3.

One end of the first linear conductor 11A is connected to the first connection conductor 31. Furthermore, the first linear conductor 11A is connected to the first pad electrode P1 through an interlayer connection conductor 51. Respective ones of the ends of the first linear conductors 11B and 11C are connected to the first connection conductors 31, and the other ends of the first linear conductors 11B and 11C are connected to the second connection conductors 41. Moreover, the first linear conductor 11C is connected to the second pad electrode P2 through an interlayer connection conductor 52. The first connection conductors 31 and the second connection conductors 41 are provided respectively at the first lateral surface VS3 and the second lateral surface VS4 of the insulator 10.

In FIG. 3, (5) and (6) denote configurations of the base material layer 1e. Second linear conductors 21A, 21B and 21C are provided at one principal surface (front surface in FIG. 3) of the base material layer 1e denoted by (5). The second linear conductors 21A, 21B and 21C are each a conductor pattern that is formed, for example, by providing a conductor film, such as a Cu film, at the one principal surface of the base material layer 1e with a plating process, for example, and by patterning the conductor film with photolithography. Alternatively, the second linear conductors 21A, 21B and 21C may be formed by screen printing of a conductive paste, for example.

The second linear conductors 21A and 21B are each a conductor pattern preferably having a parallelogram shape in a plan view, and those electrodes extend from one side of the base material layer 1e in a widthwise direction thereof (i.e., from a lower side of the base material layer 1e in FIG. 3) toward the other side (i.e., the upper side of the base material layer 1e in FIG. 3). The second linear conductor 21A is arranged near one side of the base material layer 1e in a lengthwise direction thereof (i.e., a left side of the base material layer 1e in FIG. 3). A plurality of the second linear conductors 21B, i.e., eighteen, are arranged side by side along the lengthwise direction of the base material layer 1e.

The second linear conductor 21C is a conductor pattern having a trapezoidal or substantially trapezoidal shape in a plan view. The trapezoidal conductor pattern includes a lower base facing (reaching) the one side of the base material layer 1e in the widthwise direction (i.e., the lower side of the base material layer 1e in FIG. 3), and an upper base defining an end portion E2. Thus, the conductor pattern of the second linear conductor 21C has a tapered shape gradually thinning from the one side of the base material layer 1e in the widthwise direction (i.e., from the lower side of the base material layer 1e in FIG. 3) toward the other side (i.e., the upper side of the base material layer 1e in FIG. 3). The second linear conductor 21C is arranged near the other side of the base material layer 1e in the lengthwise direction (i.e., a right side of the base material layer 1e in FIG. 3). Because of the tapered shape of the second linear conductor 21C that is arranged on the outermost side of the later-described coil conductor along the direction of the winding axis AX1 of the coil conductor (i.e., along the X direction), an increase in volume of the coil antenna 101 is significantly reduced or prevent while the number of windings of the coil conductor is increased. In other words, the second linear conductor 21A, the eighteen second linear conductors 21B, and the second linear conductor 21C are successively arranged, as illustrated in FIG. 3, along the lengthwise direction of the base material layer 1e.

Respective one ends of the second linear conductors 21A and 21B are connected to the first connection conductors 31, and the other ends of the second linear conductors 21A and 21B are connected to the second connection conductors 41. Moreover, the second linear conductor 21A is connected to the third pad electrode P3 through an interlayer connection conductor 53. One end of the second linear conductor 21C is connected to the first connection conductor 31 that is provided at one lateral surface of the base material layer 1d in the widthwise direction (i.e., at the lower lateral surface of the base material layer 1d in FIG. 3). Furthermore, the second linear conductor 21C is connected to the fourth pad electrode P4 through an interlayer connection conductor 54. As described above, the first connection conductors 31 and the second connection conductors 41 are provided respectively at the first lateral surface VS3 and the second lateral surface VS4 of the insulator 10.

The third pad electrode P3, the fourth pad electrode P4, and the dummy electrodes N2 are provided at the other principal surface of the base material layer 1e denoted by (6). The third pad electrode P3 and the fourth pad electrode P4 are each a conductor pattern having a rectangular or substantially rectangular shape in a plan view, and those electrodes are arranged near both end portions of the base material layer 1e in the lengthwise direction. The dummy electrodes N2 are each a conductor pattern having a rectangular or substantially rectangular shape in a plan view, and three dummy electrodes N2 are arranged side by side along the lengthwise direction of the base material layer 1e between the third pad electrode P3 and the fourth pad electrode P4. In other words, the third pad electrode P3, the three dummy electrodes N2, and the fourth pad electrode P4 are successively arranged, as illustrated in FIG. 3, along the lengthwise direction of the base material layer 1e.

Thus, a rectangular or substantially rectangular helical coil conductor having about 20 turns, for example, is defined by the first linear conductors 11A to 11C, the first connection conductors 31, the second linear conductors 21A to 21C, and the second connection conductors 41. In other words, the coil conductor is provided on or in the insulator 10 that is defined by laminating the plurality of base material layers 1a to 1e.

As illustrated in FIG. 1, the coil conductor of the coil antenna 101 has the winding axis AX1. In this preferred embodiment, the winding axis AX1 of the coil conductor is positioned to extend along the first principal surface VS1 and the second principal surface VS2 of the insulator 10, and it is parallel to the lengthwise direction (X direction) of the insulator 10.

In this preferred embodiment, the end portion E1 of the first linear conductor 11A corresponds to a “first end” of the coil conductor, and the end portion E2 of the second linear conductor 21C corresponds to a “second end” of the coil conductor. Thus, the coil conductor includes the first end and the second end.

It is to be noted that the “first end side” and the “second end side” of the coil conductor according to the present preferred embodiment of the present invention do not imply only the very close vicinity of the first end (end portion E1) and the second end (end portion E2) of the coil conductor. By way of example, a portion of the coil conductor corresponding to about ⅓ of its entire length, starting from the first end (end portion E1) of the coil conductor toward the second end (end portion E2) is called the “first end side”. A portion of the coil conductor corresponding to about ⅓ of its entire length, starting from the second end (end portion E2) of the coil conductor toward the first end (end portion E1) is called the “second end side”. Thus, the first pad electrode P1 and the third pad electrode P3 are connected to the coil conductor in the portion of the coil conductor corresponding to about ⅓ of the entire length, starting from the first end of the coil conductor, and the second pad electrode P2 and the fourth pad electrode P4 are connected to the coil conductor in the portion of the coil conductor corresponding to about ⅓ of the entire length, starting from the second end of the coil conductor, for example.

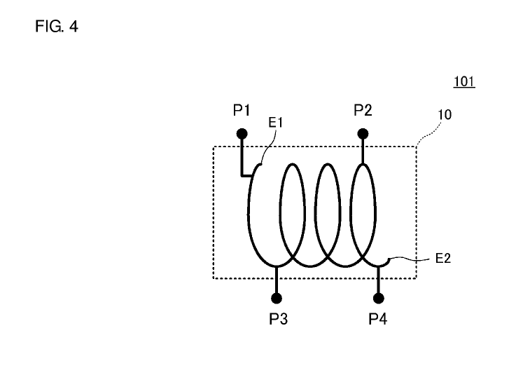

FIG. 4 is a circuit diagram of the coil antenna 101 according to the first preferred embodiment of the present invention.

As illustrated in FIG. 4, the coil conductor is provided between the first pad electrode P1 and the second pad electrode P2, between the first pad electrode P1 and the fourth pad electrode P4, between the third pad electrode P3 and the fourth pad electrode P4, and between the third pad electrode P3 and the second pad electrode P2.

In the coil antenna 101 according to this preferred embodiment, the pad electrodes connected to the coil conductor are provided at each of the first principal surface VS1 and the second principal surface VS2 of the insulator 10. Therefore, each of the first principal surface VS1 and the second principal surface VS2 is able to be optionally utilized as a mounting surface, and the coil antenna adaptable for various connection methods is realized.

In this Description, the term “mounting surface” implies a surface on which is provided a pad electrode to be connected to, for example, a land of a wiring board to which an inductor element or a coil antenna is mounted. In other words, the term “mounting surface” implies a surface on which a pad electrode allowing a conductive bonding material, such as a solder, to be formed thereon, or a wire or the like to be bonded thereto, is provided.

Furthermore, the first pad electrode P1 is connected to the first linear conductor 11A through the interlayer connection conductor 51. Thus, the first pad electrode P1 is electrically connected to the first end side (i.e., the vicinity of the end portion E1) of the coil conductor. In this preferred embodiment, the interlayer connection conductor 51 corresponds to a “first connection conductor”.

The second pad electrode P2 is connected to the first linear conductor 11C through the interlayer connection conductor 52. Thus, the second pad electrode P2 is electrically connected to the second end side (i.e., the vicinity of the end portion E2) of the coil conductor. In this preferred embodiment, the interlayer connection conductor 52 corresponds to a “second connection conductor”.

The third pad electrode P3 is connected to the second linear conductor 21A through the interlayer connection conductor 53. Thus, the third pad electrode P3 is electrically connected to the first end side (i.e., the vicinity of the end portion E1) of the coil conductor. In this preferred embodiment, the interlayer connection conductor 53 corresponds to a “third connection conductor”.

The fourth pad electrode P4 is connected to the second linear conductor 21C through the interlayer connection conductor 54. Thus, the fourth pad electrode P4 is electrically connected to the second end side (i.e., the vicinity of the end portion E2) of the coil conductor. In this preferred embodiment, the interlayer connection conductor 54 corresponds to a “fourth connection conductor”.

In the coil antenna 101, as illustrated in FIG. 1, the first pad electrode P1, the second pad electrode P2, the third pad electrode P3, the fourth pad electrode P4, and the interlayer connection conductors 51, 52, 53 and 54 (i.e., the first connection conductor, the second connection conductor, the third connection conductor, and the fourth connection conductor) are arranged outside a coil aperture CP of the coil conductor when viewed from the direction of the winding axis AX1 of the coil conductor (i.e., from the X direction).

With the configuration described above, the inductor element having stable inductance components can be realized because the first pad electrode P1, the second pad electrode P2, the third pad electrode P3, the fourth pad electrode P4, and the interlayer connection conductors 51, 52, 53 and 54 (i.e., the first connection conductor, the second connection conductor, the third connection conductor, and the fourth connection conductor) do not interfere with the coil aperture of the coil conductor.

With the configuration described above, the coil antenna exhibiting good communication characteristics can be realized because the first pad electrode P1, the second pad electrode P2, the third pad electrode P3, the fourth pad electrode P4, and the interlayer connection conductors 51, 52, 53 and 54 (i.e., the first connection conductor, the second connection conductor, the third connection conductor, and the fourth connection conductor) do not impede magnetic flux passing through the coil aperture.

Moreover, in the coil antenna 101, the first linear conductors 11A, 11B and 11C, the second linear conductors 21A, 21B and 21C, the first connection conductors 31, and the second connection conductors 41 are preferably not buried in a magnetic body. Therefore, a magnetic path of magnetic flux generated from the coil antenna 101 only defines an open magnetic path, and the magnetic flux generated from the coil antenna 101 is caused to spread outward of the insulator 10 from the first principal surface VS1, the second principal surface VS2, the first lateral surface VS3, and the second lateral surface VS4 of the insulator 10. Accordingly, the coil antenna 101 and a coil antenna on the communication counterpart side are more apt to establish magnetic field coupling, and the coupling coefficient between the coil antenna 101 and the coil antenna on the communication counterpart side is increased, thus resulting in better communication characteristics. Stated in another way, in the case of the insulator 10 including a magnetic body, the coil antenna 101 is able to be more easily magnetically coupled to the coil antenna on the communication counterpart side by using such a configuration that at least portion of the coil conductor is exposed from the magnetic body when viewed from the direction of the winding axis AX1 of the coil conductor.

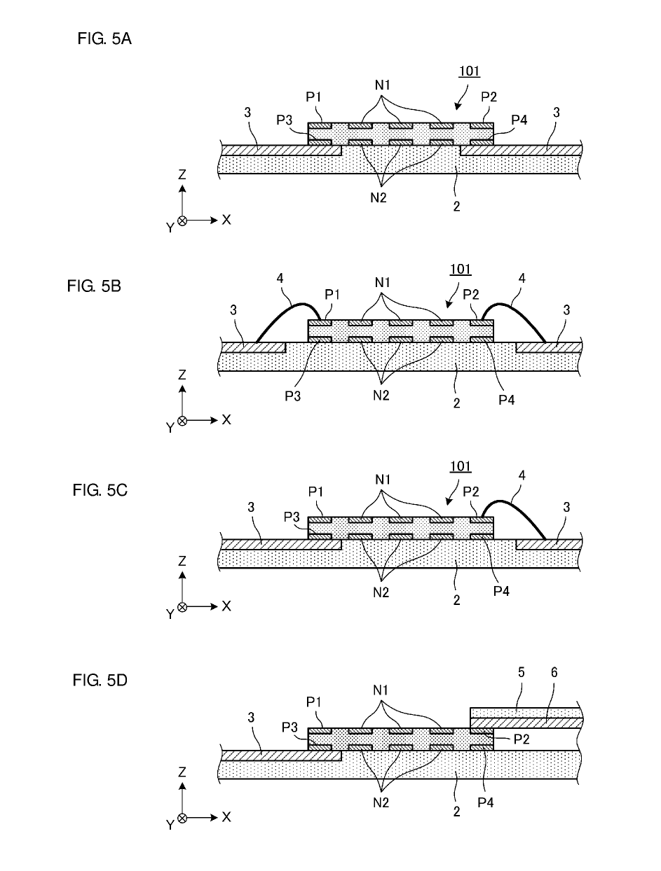

A variety of connection methods for the coil antenna 101 will be described below with reference to the drawings. FIG. 5A is a sectional view illustrating the coil antenna 101 in a state mounted using a first connection method, FIG. 5B is a sectional view illustrating the coil antenna 101 in a state mounted using a second connection method, FIG. 5C is a sectional view illustrating the coil antenna 101 in a state mounted using a third connection method, and FIG. 5D is a sectional view illustrating the coil antenna 101 in a state mounted using a fourth connection method. For easier understanding of structures, the coil conductors are not illustrated in FIGS. 5A-5D.

According to the first connection method illustrated in FIG. 5A, the coil antenna 101 is connected to conductors 3, which are provided at a principal surface of a wiring board 2, with the aid a conductive bonding material such as, for example, a solder. More specifically, the third pad electrode P3 and the fourth pad electrode P4 are electrically connected to the conductors 3, which are provided on or in the wiring board 2, for electrical conduction to a power feed circuit. According to this connection method, the coil conductor between the third pad electrode P3 and the fourth pad electrode P4 is utilized. The wiring board 2 is, for example, a printed wiring board.

According to the second connection method illustrated in FIG. 5B, the coil antenna 101 is connected to conductors 3, which are provided at the principal surface of the wiring board 2, through wires 4 (i.e., with wire bonding). More specifically, the first pad electrode P1 and the second pad electrode P2 are electrically connected to the conductors 3, which are provided on or in the wiring board 2, through the wire 4 (i.e., with wire bonding) for electrical conduction to the power feed circuit. According to this connection method, the coil conductor between the first pad electrode P1 and the second pad electrode P2 is utilized.

According to the third connection method illustrated in FIG. 5C, the third pad electrode P3 is connected to the conductor 3, which is provided on or in the wiring board 2, with the aid of a conductive bonding material such as a solder, and the second pad electrode P2 is connected to the conductor 3 through the wire 4 (i.e., with wire bonding). Thus, the third pad electrode P3 and the second pad electrode P2 are electrically conducted to the power feed circuit. According to this connection method, the coil conductor between the third pad electrode P3 and the second pad electrode P2 is utilized.

According to the fourth connection method illustrated in FIG. 5D, the third pad electrode P3 is connected to the conductor 3, which is provided on or in the wiring board 2, with the aid of a conductive bonding material such as a solder, and the second pad electrode P2 is connected to a conductor 6, which is provided on or in a wiring board 5, with the aid a conductive bonding material such as a solder. Thus, the third pad electrode P3 and the second pad electrode P2 are electrically conducted to the power feed circuit. The wiring board 2 is a flexible printed wiring board, for example, and the conductor 6 is a conductor pattern provided on or in the flexible printed board. According to this connection method, too, the coil conductor between the third pad electrode P3 and the second pad electrode P2 is utilized.

While the above connection methods have been described in relation to examples of electrically conducting pairs of the first pad electrode P1 and the second pad electrode P2, the third pad electrode P3 and the fourth pad electrode P4, and the third pad electrode P3 and the second pad electrode P2 to the power feed circuit, the present invention is not limited to those examples. As another connection method, the first pad electrode P1 and the fourth pad electrode P4 may be electrically conducted to the power feed circuit.

While the above connection methods have been described in relation to an example of utilizing, as the mounting surface, the second principal surface of the coil antenna 101 (i.e., the surface on which the third pad electrode P3 and the fourth pad electrode P4 are provided), the present invention is not limited to such an example. In another example, the first principal surface of the coil antenna 101 (i.e., the surface on which the first pad electrode P1 and the second pad electrode P2 are formed) may be utilized as the mounting surface.

In the coil antenna 101 according to this preferred embodiment, as illustrated in FIGS. 2A and 2C, the first pad electrode P1 and the second pad electrode P2 are in a point symmetrical relationship with respect to a center DC of the insulator 10 when looking at the coil antenna 101 in a plan view from the Z direction (i.e., the direction parallel to the third side SL3 of the insulator 10). Similarly, the third pad electrode P3 and the fourth pad electrode P4 are in a point symmetrical relationship with respect to the center DC of the insulator 10 when looking at the coil antenna 101 in a plan view from the Z direction. With such a configuration, even when the coil antenna 101 is rotated by 180° with respect to a Z axis LZ passing the center DC of the insulator 10, the pad electrodes electrically connected to the coil conductor remain in the same positional relationship relative to one another.

Furthermore, in the coil antenna 101 according to this preferred embodiment, as illustrated in FIG. 2B, the first pad electrode P1 and the fourth pad electrode P4 are preferably in a point symmetrical relationship with respect to the center DC of the insulator 10 when looking at the coil antenna 101 in a plan view from the Y direction (i.e., the direction parallel to the second side SL2 of the first principal surface VS1). Similarly, the second pad electrode P2 and the third pad electrode P3 are in a point symmetrical relationship with respect to the center DC of the insulator 10 when looking at the coil antenna 101 in a plan view from the Y direction. With such a configuration, even when the coil antenna 101 is rotated by 180° with respect to a Y axis LY passing the center DC of the insulator 10, the pad electrodes electrically connected to the coil conductor remain in the same positional relationship relative to one another.

Moreover, in the coil antenna 101 according to this preferred embodiment, as illustrated in FIG. 1B, the first pad electrode P1 and the third pad electrode P3 are preferably in a point symmetrical relationship with respect to the center DC of the insulator 10 when looking at the coil antenna 101 in a plan view from the X direction (i.e., the direction parallel to the first side SL1 of the first principal surface VS1). Similarly, the second pad electrode P2 and the fourth pad electrode P4 are preferably in a point symmetrical relationship with respect to the center DC of the insulator 10 when looking at the coil antenna 101 in a plan view from the X direction. With such a configuration, even when the coil antenna 101 is rotated by 180° with respect to an X axis LX passing the center DC of the insulator 10, the pad electrodes electrically connected to the coil conductor remain in the same positional relationship relative to one another.

With the above-described configurations, even when the coil antenna 101 is rotated by 180° with respect to any of the X axis LX, the Y axis LY, and the Z axis LZ each passing the center DC of the insulator 10, the pad electrodes electrically connected to the coil conductor remain in the same positional relationship relative to one another. Therefore, when the coil antenna 101 is mounted to a printed wiring board, for example, the first principal surface VS1 and the second principal surface VS2 can be each optionally utilized as the mounting surface. In addition, it is possible to avoid a risk that the coil antenna is not electrically conducted to the feed circuit and the coil antenna does not function with a false operation of mounting the surface of the coil antenna, which is not the mounting surface, to a printed wiring board, for example.

The X axis LX corresponds to a “first axis”, the Y axis LY corresponds to a “second axis”, and the Z axis LZ corresponds to a “third axis”.

Furthermore, with the above-described configurations, an inductance component between the first pad electrode P1 and the second pad electrode P2 when the first principal surface VS1 of the insulator 10 is utilized as the mounting surface is equal or substantially equal to an inductance component between the third pad electrode P3 and the fourth pad electrode P4 when the second principal surface VS2 of the insulator 10 is utilized as the mounting surface. Moreover, interactions between the coil antenna 101 and external members, such as parasitic capacitances generated between ground conductors, etc. provided on or in a wiring board to which the coil antenna is mounted and the first linear conductors 11A, 11B and 11C, when the first principal surface VS1 of the insulator 10 is utilized as the mounting surface are substantially the same as interactions between the coil antenna 101 and the external members, such as parasitic capacitances generated between the ground conductors, etc. provided on or in the wiring board to which the coil antenna is mounted and the second linear conductors 21A, 21B and 21C when the second principal surface VS2 is utilized as the mounting surface.

Accordingly, electrical and magnetic characteristics, such as impedance and radiation characteristics, of the coil antenna 101 are not changed significantly depending on which one of the principal surfaces is utilized as the mounting surface, and the coil antenna having stable characteristics is realized.

In the coil antenna 101 according to this preferred embodiment, the pad electrodes electrically connected to the coil conductor remain in the same positional relationship relative to one another even when the coil antenna 101 is rotated by 180° about any of the X axis, the Y axis, and the Z axis. In other words, the layout of the pad electrodes electrically connected to the coil conductor has 180°-rotational symmetry.

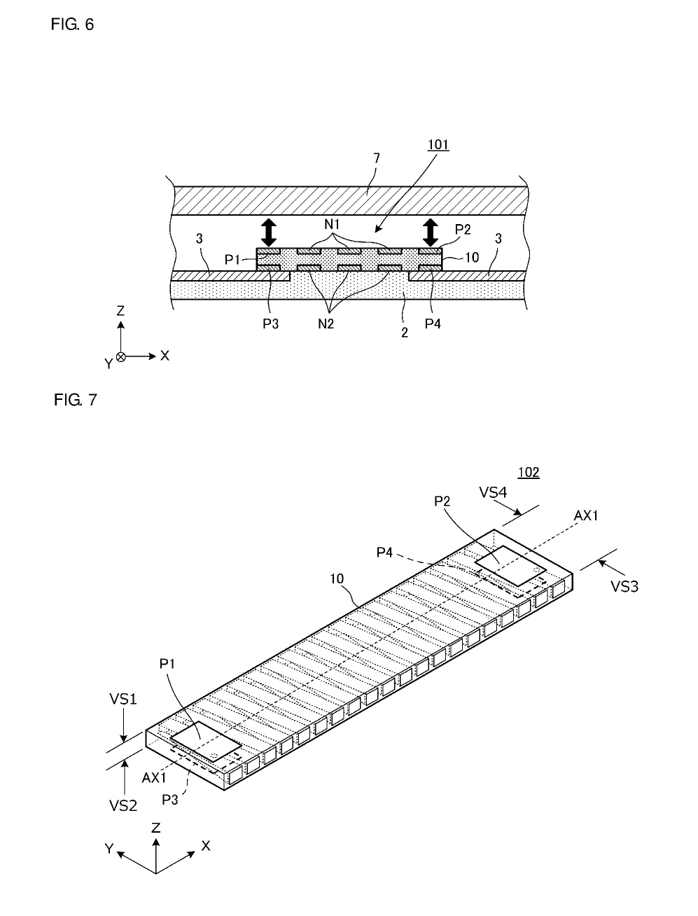

FIG. 6 is a detailed sectional view of an antenna device including the coil antenna 101 according to the first preferred embodiment and a planar conductor 7.

The antenna device illustrated in FIG. 6 includes the coil antenna 101 and the planar conductor 7. The third pad electrode P3 and the fourth pad electrode P4 of the coil antenna 101 are electrically connected to the conductors 3, which are provided on or in the wiring board 2, for electrical conduction to the power feed circuit. The planar conductor 7 is, for example, a portion or the entirety of a ground conductor, a shield member, a battery pack, or a casing, which are formed or equipped in an electronic device.

As illustrated in FIG. 6, the planar conductor 7 is positioned close (adjacent) to the first pad electrode P1 and the second pad electrode P2. Therefore, the planar conductor 7 is capacitively coupled to the first pad electrode P1 and the second pad electrode P2 through an electric field (see arrows in FIG. 6).

Hence the planar conductor 7 defines and functions as a booster antenna of the coil antenna 101. In comparison with the case of including only the coil antenna 101, therefore, an effective coil aperture substantially defining and functioning as an antenna is increased, and magnetic flux is able to be radiated (or collected) over a wider range and a longer distance. This makes it easier to establish coupling to an antenna coil on the communication counterpart side. As a result, the coil antenna having good communication characteristics is able to be realized with a simple configuration without using a large-sized antenna coil.

The phrase “close to” does not imply only a range very close to the first pad electrode P1 and the second pad electrode P2. The phrase “close to” implies a range “close to” such an extent that the planar conductor 7 is capacitively coupled to the first pad electrode P1 and the second pad electrode P2 through an electric field, thus causing the planar conductor 7 to provide a boost effect. The phrase “close to” is defined as representing, for example, the case where the distance between the planar conductor 7 and each of the first pad electrode P1 and the second pad electrode P2 is not more than the length of the insulator 10 in the lengthwise direction (X direction).

While the first preferred embodiment has been described in relation to an example in which the lengthwise direction of the insulator 10 is aligned with the horizontal direction (X direction) and the widthwise direction is aligned with the vertical direction (Y direction), the present invention is not limited to such an example. In another example, the widthwise direction of the insulator 10 may be aligned with the horizontal direction (X direction) and the lengthwise direction may be aligned with the vertical direction (Y direction).

While the first preferred embodiment of the present invention has been described in relation to an example in which the insulator 10 has a rectangular or substantially rectangular parallelepiped shape, the present invention is not limited to such an example. The three-dimensional shape of the insulator 10 may be optionally modified into a cubic shape, a polygonal columnar shape, a circular columnar shape, an elliptical columnar shape, etc., for example, insofar as the insulator 10 includes the first principal surface VS1 and the second principal surface VS2 and the coil conductor can be provided at those principal surfaces.

While the first preferred embodiment of the present invention has been described in relation to an exemplary structure in which the insulator 10 includes magnetic layers (i.e., the base material layers 1b, 1c and 1d) sandwiched between nonmagnetic layers (i.e., the base material layers 1a and 1e), the present invention is not limited to such a structure. The insulator 10 may be a multilayer body that is defined only by magnetic layers without including nonmagnetic layers.

While the first preferred embodiment has been described in relation to an example in which the insulator 10 is the multilayer body defined by the base material layers 1a, 1b, 1c, 1d and 1e, the present invention is not limited to such an example. The insulator 10 may be integrally formed of, for example, a resin member containing magnetic powder, such as ferrite powder.

While the first preferred embodiment has been described in relation to an example in which the first connection conductor 31 and the second connection conductor 41 are each the conductor pattern extending in the thickness direction (Z direction), the present invention is not limited to such an example. The first connection conductor 31 and the second connection conductor 41 may be each defined by a plurality of interlayer connection conductors extending in the thickness direction (Z direction), or by a metal post. The interlayer connection conductor is, for example, a via conductor that is defined by forming a via hole in the base material layer, and by filling a conductive paste into the via hole. The metal post is preferably, for example, a Cu-made pin having a circular columnar shape.

While the first preferred embodiment has been described in relation to an example in which the winding axis AX1 of the coil conductor is parallel to the lengthwise direction of the insulator 10 (i.e., the X direction), the present invention is not limited to such an example. The coil antenna may have a configuration that the winding axis AX1 of the coil conductor is parallel to the widthwise direction of the insulator 10 (i.e., the Y direction), or parallel to the thickness direction (i.e., the Z direction).

When the insulator 10 included in the coil antenna 101 has a rectangular or substantially rectangular parallelepiped shape, the winding axis AX of the coil conductor is preferably parallel to any one of the first side SL1, the second side SL2, and the third side SL3 of the insulator 10. With such a configuration, even when the coil antenna 101 is rotated by 180° about the axis parallel to any one of the first side SL1, the second side SL2, and the third side SL3, the one being parallel to the winding axis AX of the coil conductor, the direction of the winding axis AX of the coil conductor is not changed. Therefore, the magnetic-flux radiation characteristics of the coil antenna 101 are not changed with the above-described rotation of the coil antenna. In other words, the magnetic-flux radiation characteristics of the coil antenna 101 are not dependent on the mounting direction of the coil antenna 101.

While this preferred embodiment has been described in relation to an example in which the coil conductor is defined in a rectangular or substantially rectangular helical shape with about 20 turns, the present invention is not limited to such an example. The number of turns, the shape, etc. of the coil conductor can be optionally modified depending on the inductance component, the shape of the insulator 10, etc., which are demanded in practical use.

Furthermore, since the dummy electrodes are formed, as described above, at the first principal surface VS1 and the second principal surface VS2 of the insulator 10 in a symmetrical relation, it is possible to effectively reduce or prevent warpage of the insulator 10, which is generated due to residual stress during firing.

While the first preferred embodiment has been described in relation to an example in which the dummy electrodes N1 and N2 preferably have the same shape as the first to fourth pad electrodes P1 to P4, the present invention is not limited to such an example. The dummy electrodes may be different in shape, size, etc. from the pad electrodes. As an alternative, symbols and characters representing the name of the manufacturing maker, the product serial number, and the lot number may be disposed instead of the dummy electrodes.

While the first preferred embodiment has been described in relation to an example in which the dummy electrodes N1 and N2 preferably are respectively located between the first pad electrode P1 and the second pad electrode P2 and between the third pad electrode P3 and the fourth pad electrode P4, positions where the dummy electrodes are provided are not limited to such an example. In another example, the pad electrode may be sandwiched between the dummy electrodes, or the dummy electrodes may be arranged only near the pad electrode on one side.

### Second Preferred Embodiment

FIG. 7 is an external perspective view of a coil antenna 102 according to a second preferred embodiment of the present invention.

The coil antenna 102 according to the second preferred embodiment is preferably different from the coil antenna 101 according to the first preferred embodiment by not including any dummy electrodes at the first principal surface VS1 and the second principal surface VS2 of the insulator 10. The other configuration is preferably the same as that of the coil antenna 101 according to the first preferred embodiment.

In the second preferred embodiment thus defined, the coil antenna 102 has the same basic configuration as the coil antenna 101 according to the first preferred embodiment, and ensures similar operation and advantageous effects to those in the coil antenna 101. As represented by the second preferred embodiment, the dummy electrodes are not essential components.

### Third Preferred Embodiment

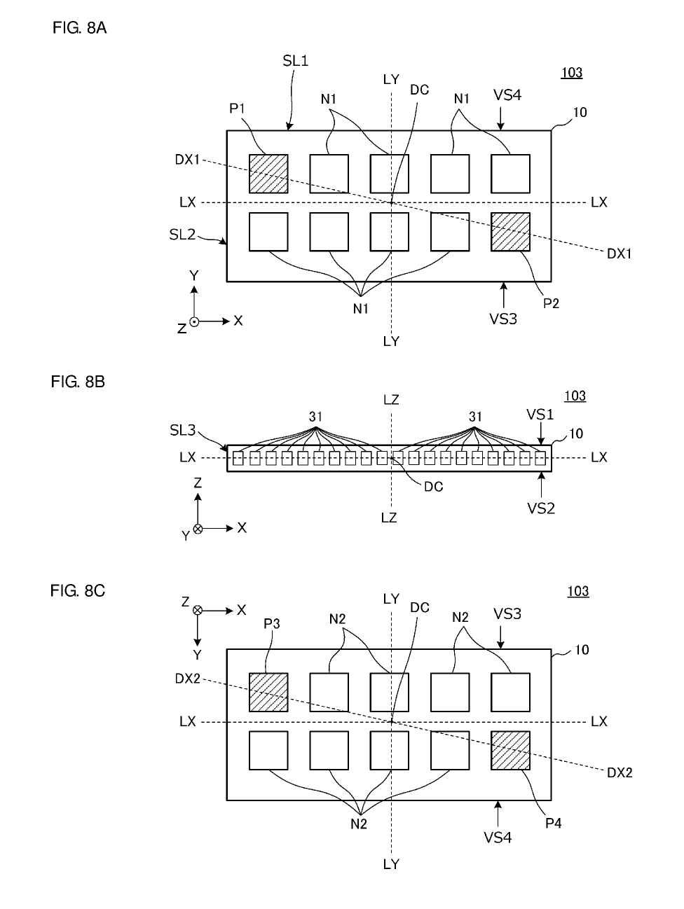

FIG. 8A is a plan view of a coil antenna 103 according to a third preferred embodiment of the present invention, FIG. 8B is a front view of the coil antenna 103, and FIG. 8C is a bottom view of the coil antenna 103.

The coil antenna 103 according to the third preferred embodiment is preferably different from the coil antenna 101 according to the first preferred embodiment in that the pad electrodes and the dummy electrodes N1 and N2 are arranged in two rows extending in the lengthwise direction of the insulator 10 (i.e., the X direction). The other configuration is preferably substantially the same as that of the coil antenna 101.

Different points from the coil antenna 101 according to the first preferred embodiment will be described below.

The first pad electrode P1, the second pad electrode P2, and eight dummy electrodes N1 are provided at the first principal surface VS1 of the insulator 10. When looking at the first principal surface VS1, the first pad electrode P1 and the second pad electrode P2 are arranged respectively near a first corner (upper left corner in FIG. 8) of the insulator 10 and near a second corner (lower right corner in FIG. 8) that is an opposing corner diagonally positioned relative to the first corner.

The first pad electrode P1 and four dummy electrodes N1 are successively arranged, as illustrated in FIG. 8A, along the lengthwise direction (X direction) starting from the vicinity of the first corner of the insulator 10. The second pad electrode P2 and other four dummy electrodes N1 are successively arranged, as illustrated in FIG. 8A, along the lengthwise direction (X direction) starting from the vicinity of the second corner of the insulator 10.

Thus, as illustrated in FIG. 8A, the first pad electrode P1, the second pad electrode P2, and the eight dummy electrodes N1 are arranged in a pattern of 2 rows and 5 columns when looking at the first principal surface VS1.

The third pad electrode P3, the fourth pad electrode P4, and eight dummy electrodes N2 are provided at the second principal surface of the insulator 10. When looking at the second principal surface VS2, the third pad electrode P3 and the fourth pad electrode P4 are arranged respectively near the first corner (upper left corner in FIG. 8) of the insulator 10 and near the second corner (lower right corner in FIG. 8) that is an opposing corner diagonally positioned relative to the first corner.

The third pad electrode P3 and four dummy electrodes N2 are successively arranged, as illustrated in FIG. 8C, along the lengthwise direction (X direction) starting from the vicinity of the first corner of the insulator 10. The fourth pad electrode P4 and other four dummy electrodes N2 are successively arranged, as illustrated in FIG. 8C, along the lengthwise direction (X direction) starting from the vicinity of the second corner of the insulator 10.

Thus, as illustrated in FIG. 8C, the third pad electrode P3, the fourth pad electrode P4, and the eight dummy electrodes N2 are arranged in a pattern of 2 rows and 5 columns when looking at the second principal surface VS2.

Also in the thus-defined coil antenna 103 according to this preferred embodiment, the pad electrodes connected to the coil conductor are provided at each of the first principal surface VS1 and the second principal surface VS2 of the insulator 10. Therefore, as in the coil antenna 101 according to the first preferred embodiment, the first principal surface VS1 and the second principal surface VS2 can be each optionally utilized as the mounting surface, and the coil antenna adaptable for various connection methods can be realized.

In the coil antenna 103 according to this preferred embodiment, as illustrated in FIGS. 8A and 8C, the first pad electrode P1 and the second pad electrode P2 are preferably in a point symmetrical relationship with respect to the center DC of the insulator 10 when looking at the coil antenna 103 in a plan view from the Z direction (i.e., the direction parallel to the third side SL3 of the insulator 10). Similarly, the third pad electrode P3 and the fourth pad electrode P4 are preferably in a point symmetrical relationship with respect to the center DC of the insulator 10 when looking at the coil antenna 103 in a plan view from the Z direction. With such a configuration, even when the coil antenna 103 is rotated by 180° with respect to the Z axis LZ passing the center DC of the insulator 10, the pad electrodes electrically connected to the coil conductor remain in the same positional relationship relative to one another.

Furthermore, in the coil antenna 103 according to this preferred embodiment, as illustrated in FIG. 8B, the first pad electrode P1 and the fourth pad electrode P4 are preferably in a point symmetrical relationship with respect to the center DC of the insulator 10 when looking at the coil antenna 103 in a plan view from the Y direction (i.e., the direction parallel to the second side SL2 of the first principal surface VS1). Similarly, the second pad electrode P2 and the third pad electrode P3 are preferably in a point symmetrical relationship with respect to the center DC of the insulator 10 when looking at the coil antenna 103 in a plan view from the Y direction. With such a configuration, even when the coil antenna 103 is rotated by 180° with respect to the Y axis LY passing the center DC of the insulator 10, the pad electrodes electrically connected to the coil conductor remain in the same positional relationship relative to one another.

Moreover, in the coil antenna 103 according to this preferred embodiment, the first pad electrode P1 and the third pad electrode P3 are preferably in a point symmetrical relationship with respect to the center DC of the insulator 10 when looking at the coil antenna 103 in a plan view from the X direction (i.e., the direction parallel to the first side SL1 of the first principal surface VS1). Similarly, the second pad electrode P2 and the fourth pad electrode P4 are preferably arranged in a point symmetrical relationship with respect to the center DC of the insulator 10 when looking at the coil antenna 103 in a plan view from the X direction. With such a configuration, even when the coil antenna 103 is rotated by 180° with respect to the X axis LX passing the center DC of the insulator 10, the pad electrodes electrically connected to the coil conductor remain in the same positional relationship relative to one another.

Thus, even when the coil antenna 103 is rotated by 180° with respect to any of the X axis LX, the Y axis LY, and the Z axis LZ each passing the center DC of the insulator 10, the pad electrodes electrically connected to the coil conductor remain in the same positional relationship relative to one another. In other words, the layout of the pad electrodes electrically connected to the coil conductor has 180°-rotational symmetry. Therefore, when the coil antenna 103 is mounted to a printed wiring board, for example, each of the first principal surface VS1 and the second principal surface VS2 is able to be optionally utilized as the mounting surface. In addition, it is possible to avoid such a risk that the coil antenna is not electrically conducted to the feed circuit and the coil antenna does not function with an error of mounting the surface of the coil antenna, which is not the mounting surface, to a printed wiring board, for example.

While the third preferred embodiment has been described in relation to an example in which the layout of the pad electrodes has 180°-rotational symmetry, i.e., point symmetry, the present invention is not limited to such an example. As described in detail in a tenth preferred embodiment of the present invention, the layout of the pad electrodes arranged at the same principal surface of the insulator may have 120°-rotational symmetry (three-folded symmetry) or 90°-rotational symmetry (four-folded symmetry), for example.

Moreover, as represented by this preferred embodiment, an array (n rows and m columns) of the pad electrodes and the dummy electrodes N1 and N2 can be changed as appropriate.

In this preferred embodiment, when looking at the coil antenna 103 in a plan view from the Z direction, a direction in which the first pad electrode P1 and the second pad electrode P2 are arrayed (i.e., a direction of an axis DX1 in FIG. 8A) is not parallel to the first side SL1 and is not parallel to the second side SL2. In this preferred embodiment, however, since the first pad electrode P1 and the second pad electrode P2 are in a point symmetrical relationship with respect to the center DC of the insulator 10 when looking at the coil antenna 103 in a plan view from the Z direction, the pad electrodes electrically connected to the coil conductor remain in the same positional relationship relative to one another even when the coil antenna 103 is rotated about the Z axis LZ passing the center DC of the insulator 10.

Similarly, in this preferred embodiment, when looking at the coil antenna 103 in a plan view from the Z direction, a direction in which the third pad electrode P3 and the fourth pad electrode P4 are arrayed (i.e., a direction of an axis DX2 in FIG. 8C) is not parallel to the first side SL1 and is not parallel to the second side SL2. In this preferred embodiment, however, since the third pad electrode P3 and the fourth pad electrode P4 are arranged in a point symmetrical relationship with respect to the center DC of the insulator 10 when looking at the coil antenna 103 in a plan view from the Z direction, the pad electrodes electrically connected to the coil conductor remain in the same positional relationship relative to one another as that before the rotation even when the coil antenna 103 is rotated about the Z axis LZ passing the center DC of the insulator 10.

Thus, even when the pad electrodes and the dummy electrodes are arrayed in a pattern of two or more rows and two or more columns on each of the first principal surface VS1 and the second principal surface VS2, the coil antenna 103 is able to be electrically conducted to the power feed circuit without depending on the mounting direction of the coil antenna 103 by arranging the pad electrodes as described above.

### Fourth Preferred Embodiment

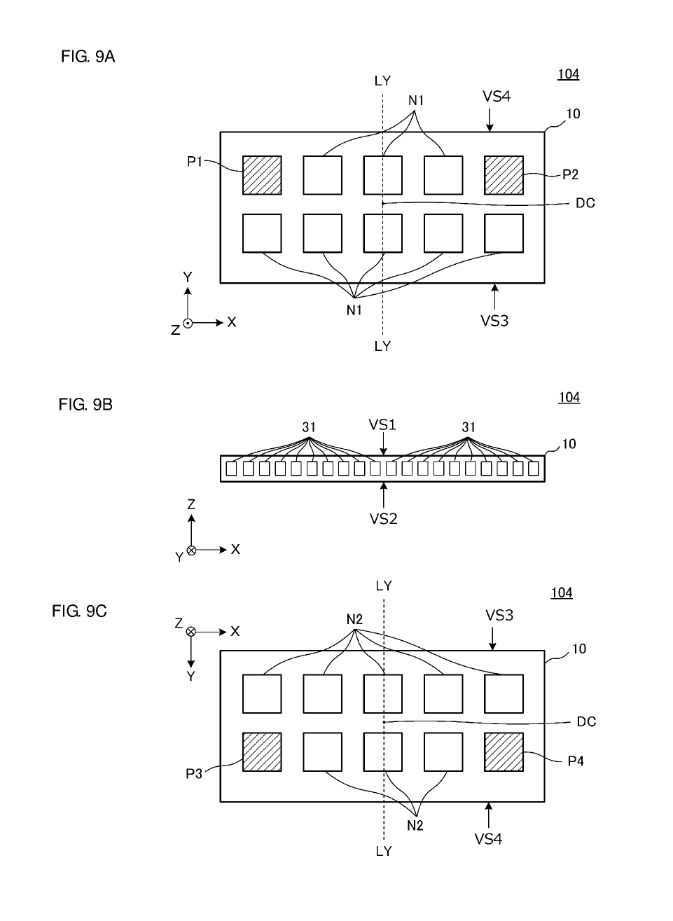

FIG. 9A is a plan view of a coil antenna 104 according to a fourth preferred embodiment of the present invention, FIG. 9B is a front view of the coil antenna 104, and FIG. 9C is a bottom view of the coil antenna 104.

The coil antenna 104 according to the fourth preferred embodiment is preferably different from the coil antenna 103 according to the third preferred embodiment in layout of the pad electrodes and the dummy electrodes N1 and N2. The other configuration is preferably substantially the same as that of the coil antenna 103.

Different points from the coil antenna 103 according to the third preferred embodiment will be described below.

The first pad electrode P1 and the second pad electrode P2 are arranged near both the end portions of the insulator 10 in the lengthwise direction thereof (i.e., the X direction). Three dummy electrodes N1 are arranged between the first pad electrode P1 and the second pad electrode P2 along the lengthwise direction of the insulator 10 (i.e., the X direction). When looking at the first principal surface VS1 of the insulator 10, the first pad electrode P1, the second pad electrode P2, and the three dummy electrodes N1 are successively arranged along the lengthwise direction (X direction) starting from the vicinity of one corner of the insulator 10 (i.e., an upper left corner of the insulator 10 in FIG. 9A). Furthermore, another five dummy electrodes N1 are successively arranged along the lengthwise direction (X direction) starting from the vicinity of an opposing corner of the insulator (i.e., a lower right corner of the insulator 10 in FIG. 9A).

Thus, as illustrated in FIG. 9A, the first pad electrode P1, the second pad electrode P2, and the eight dummy electrodes N1 are arranged in a pattern of 2 rows and 5 columns when looking at the first principal surface VS1.

The third pad electrode P3 and the fourth pad electrode P4 are arranged near both the end portions of the insulator 10 in the lengthwise direction thereof (i.e., the X direction). Three dummy electrodes N2 are arranged between the third pad electrode P3 and the fourth pad electrode P4 along the lengthwise direction of the insulator 10 (i.e., the X direction). When looking at the second principal surface VS2 of the insulator 10, the third pad electrode P3, the fourth pad electrode P4, and the three dummy electrodes N2 are successively arranged along the lengthwise direction (X direction) starting from the vicinity of one corner of the insulator 10 (i.e., a lower left corner of the insulator 10 in FIG. 9C). Furthermore, another five dummy electrodes N2 are successively arranged along the lengthwise direction (X direction) starting from the vicinity of an opposing corner of the insulator (i.e., an upper right corner of the insulator 10 in FIG. 9C).

Thus, as illustrated in FIG. 9C, the third pad electrode P3, the fourth pad electrode P4, and the eight dummy electrodes N2 are arranged in a pattern of 2 rows and 5 columns when looking at the second principal surface VS2.

Also in the thus-defined coil antenna 104 according to this preferred embodiment, the pad electrodes connected to the coil conductor are provided at each of the first principal surface VS1 and the second principal surface VS2 of the insulator 10. Therefore, as in the coil antenna 101 according to the first preferred embodiment, the first principal surface VS1 and the second principal surface VS2 can be each optionally utilized as the mounting surface, and the coil antenna adaptable for various connection methods is realized.

In the coil antenna 104, as illustrated in FIGS. 9A and 9C, the first pad electrode P1 and the second pad electrode P2 are in a 180° rotational symmetrical relationship about the Y axis LY passing the center DC of the insulator 10. The third pad electrode P3 and the fourth pad electrode P4 are in a 180° rotational symmetrical relationship about the Y axis LY passing the center DC of the insulator 10.

Thus, even when the coil antenna 104 is rotated by 180° with respect to the Y axis LY, the pad electrodes electrically connected to the coil conductor remain in the same positional relationship relative to one another.

### Fifth Preferred Embodiment

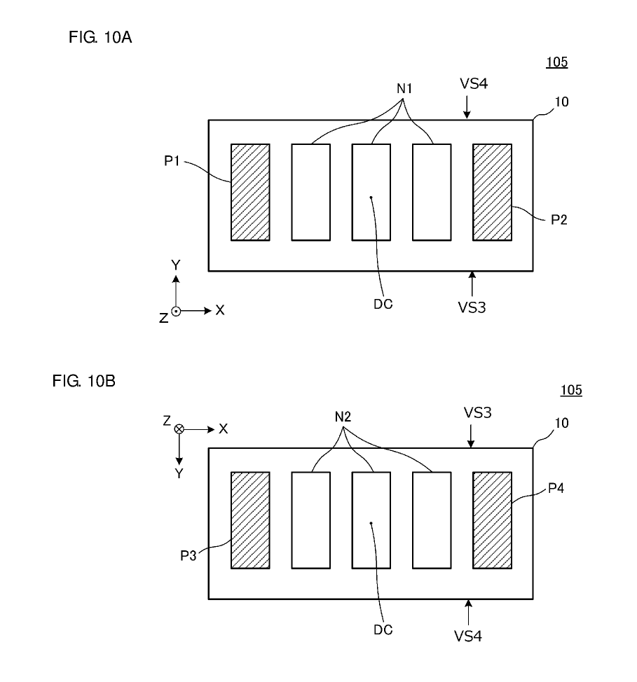

FIG. 10A is a plan view of a coil antenna 105 according to a fifth preferred embodiment of the present invention, and FIG. 10B is a bottom view of the coil antenna 105.

The coil antenna 105 according to the fifth preferred embodiment is preferably different from the coil antenna 101 according to the first preferred embodiment in shapes of the pad electrodes and the dummy electrodes N1 and N2. The other configuration is preferably substantially the same as that of the coil antenna 101.

Different points from the coil antenna 101 according to the first preferred embodiment will be described below.

The first pad electrode P1, the second pad electrode P2, and the dummy electrodes N1 are each a conductor pattern having a rectangular or substantially rectangular shape in a plan view. The third pad electrode P3, the fourth pad electrode P4, and the dummy electrodes N2 are each a conductor pattern having a rectangular or substantially rectangular shape in a plan view.

The thus-defined coil antenna 105 according to this preferred embodiment also has the same basic configuration as the coil antenna 101 according to the first preferred embodiment, and ensures similar operation and advantageous effects to those in the coil antenna 101.

As represented by this preferred embodiment, the shape, the size, etc. of the pad electrodes can be changed as appropriate. Moreover, the pad electrodes may be structured in any combination of different shapes and different sizes insofar as electrical and magnetic characteristics are not affected significantly. The shape, the size, etc. of the dummy electrodes N1 and N2 can also be changed as appropriate. Moreover, the dummy electrodes N1 and N2 may also be structured in any combination of different shapes and different sizes.

### Sixth Preferred Embodiment

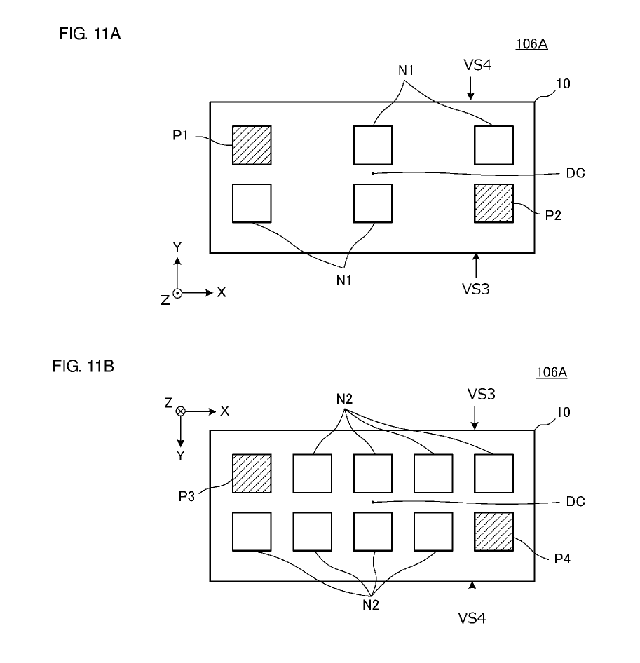

FIG. 11A is a plan view of a coil antenna 106A according to a sixth preferred embodiment of the present invention, and FIG. 11B is a bottom view of the coil antenna 106A. FIG. 12A is a plan view of a coil antenna 106B according to the sixth preferred embodiment, and FIG. 12B is a bottom view of the coil antenna 106B.

The coil antennas 106A and 106B are preferably different from the coil antenna 103 according to the third preferred embodiment in array and number of the dummy electrodes N1 and N2. The other configuration is preferably substantially the same as that of the coil antenna 103.

Different points from the coil antenna 103 according to the third preferred embodiment will be described below.

In the coil antenna 106A, as illustrated in FIGS. 11A and 11B, the number of the dummy electrodes N1 provided at the first principal surface of the insulator 10 is smaller than the number of the dummy electrodes N2 provided at the second principal surface.

In the coil antenna 106B, as illustrated in FIGS. 12A and 12B, the number of the dummy electrodes N2 provided at the second principal surface of the insulator 10 is smaller than the number of the dummy electrodes N1 provided at the first principal surface.

The thus-defined coil antennas 106A and 106B according to this preferred embodiment also have the same basic configuration as the coil antenna 101 according to the first preferred embodiment, and ensure similar operation and advantageous effects to those in the coil antenna 101.

### Seventh Preferred Embodiment

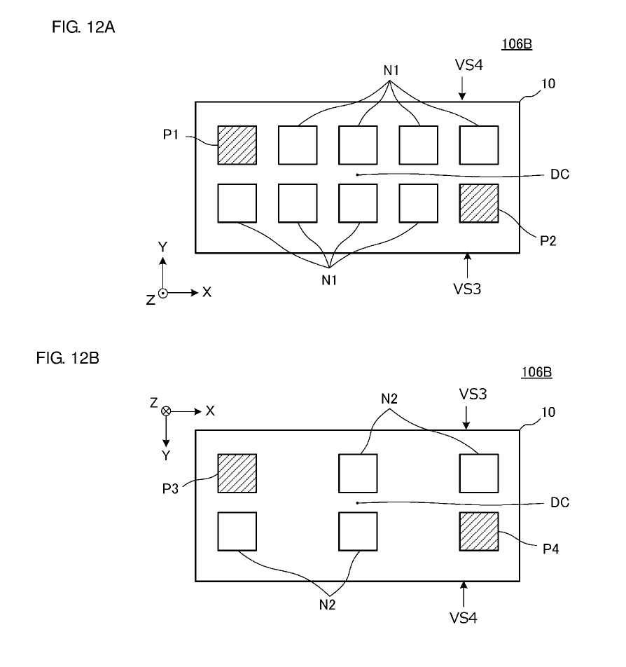

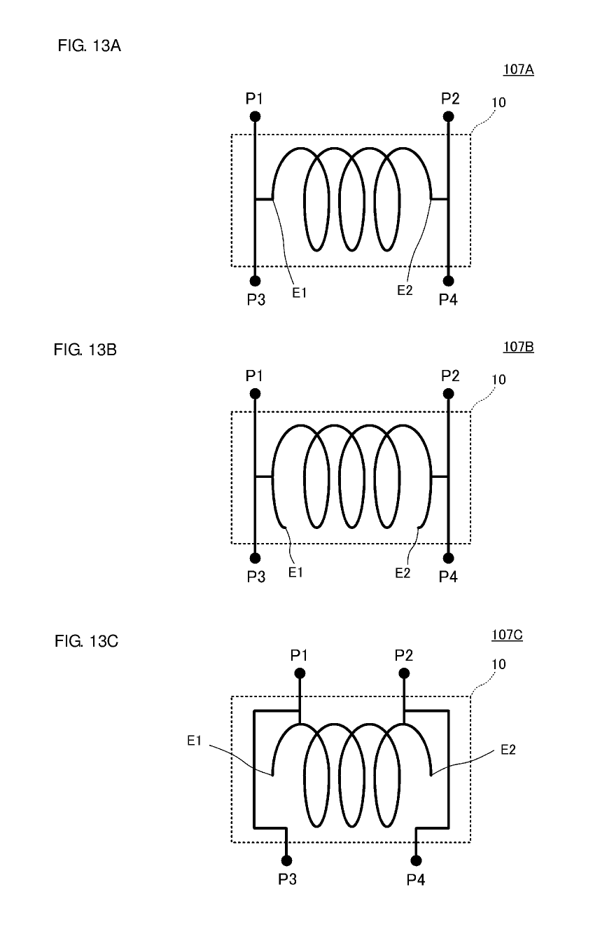

FIG. 13A is a circuit diagram of a coil antenna 107A according to a seventh preferred embodiment of the present invention, FIG. 13B is a circuit diagram of a coil antenna 107B, and FIG. 13C is a circuit diagram of a coil antenna 107C.

The coil antennas 107A, 107B and 107C are preferably different from the coil antenna 101 according to the first preferred embodiment in that the first pad electrode P1 and the third pad electrode P3 are electrically connected to the same position on the first end side. The coil antennas 107A, 107B and 107C are preferably further different from the coil antenna 101 according to the first preferred embodiment in that the second pad electrode P2 and the fourth pad electrode P4 are electrically connected to the same position on the second end side. The other configuration is preferably substantially the same as that of the coil antenna 101.

Different points from the coil antenna 101 according to the first preferred embodiment will be described below.

In the coil antenna 107A, as illustrated in FIG. 13A, the first pad electrode P1 and the third pad electrode P3 are connected to the first end (end portion E1) of the coil conductor, and the second pad electrode P2 and the fourth pad electrode P4 are connected to the second end (end portion E2) of the coil conductor. In other words, the first pad electrode P1 and the third pad electrode P3 are both electrically connected to the same position on the first end side, and the second pad electrode P2 and the fourth pad electrode P4 are both electrically connected to the same position on the second end side.

In the coil antenna 107B, as illustrated in FIG. 13B, the first pad electrode P1 and the third pad electrode P3 are connected to the first end side (in a vicinity of the end portion E1) of the coil conductor, and the second pad electrode P2 and the fourth pad electrode P4 are connected to the second end side (in a vicinity of the end portion E2) of the coil conductor. In other words, as illustrated in FIG. 13B, the first pad electrode P1 and the third pad electrode P3 are both electrically connected to the same position on the first end side, and the second pad electrode P2 and the fourth pad electrode P4 are both electrically connected to the same position on the second end side.

In the coil antenna 107C, as illustrated in FIG. 13C, the first pad electrode P1 is connected to the first end side (vicinity of the end portion E1) of the coil conductor, and the second pad electrode P2 is connected to the second end side (vicinity of the end portion E2) of the coil conductor. The third pad electrode P3 is branched from a point between the first end side of the coil conductor and the first pad electrode P1 inside the insulator 10. In other words, the third pad electrode P3 is electrically connected to the first pad electrode P1 inside the insulator 10. The fourth pad electrode P4 is branched from a point between the second end side of the coil conductor and the second pad electrode P2 inside the insulator 10. In other words, the fourth pad electrode P4 is electrically connected to the second pad electrode P2 inside the insulator 10.

Accordingly, in the coil antenna 107C, the first pad electrode P1 and the third pad electrode P3 are both electrically connected to the same position on the first end side, and the second pad electrode P2 and the fourth pad electrode P4 are both electrically connected to the same position on the second end side.

The thus-defined coil antennas 107A, 107B, and 107C according to this preferred embodiment also have the same basic configuration as the coil antenna 101 according to the first preferred embodiment, and ensure similar operation and advantageous effects to those in the coil antenna 101.

Furthermore, in each of the coil antennas 107A, 107B, and 107C according to this preferred embodiment, the first pad electrode P1 and the third pad electrode P3 are both electrically connected to the same position on the first end side, and the second pad electrode P2 and the fourth pad electrode P4 are both electrically connected to the same position on the second end side. Therefore, an inductance component between the first pad electrode P1 and the second pad electrode P2 is perfectly matched with that between the third pad electrode P3 and the fourth pad electrode P4. As a result, a coil antenna is realized in which the inductance component is always constant even when the coil antenna is connected using any of various connection methods.

Moreover, in the coil antenna 107C, the first pad electrode P1 and the third pad electrode P3 are electrically connected to each other inside the insulator 10, and the second pad electrode P2 and the fourth pad electrode P4 are electrically connected to each other inside the insulator 10. Therefore, the coil antenna is robust in its entirety. In addition, since a connected portion between the first pad electrode P1 and the third pad electrode P3 is protected by the insulator 10, reliability of the connected portion between the first pad electrode P1 and the third pad electrode P3 is high. Since a connected portion between the second pad electrode P2 and the fourth pad electrode P4 is protected by the insulator 10, reliability of the connected portion between the second pad electrode P2 and the fourth pad electrode P4 is also high.

While the coil antenna 107C according to this preferred embodiment has been described in relation to an example in which the third pad electrode P3 is branched from the point between the first end side of the coil conductor and the first pad electrode P1 inside the insulator 10, and the fourth pad electrode P4 is electrically connected to the second pad electrode P2 inside the insulator 10, the present invention is not limited to such an example. In another example, the first pad electrode P1 may be branched from a point between the first end side of the coil conductor and the third pad electrode P3 inside the insulator 10, and the second pad electrode P2 may be electrically connected to the fourth pad electrode P4 inside the insulator 10.

### Eighth Preferred Embodiment

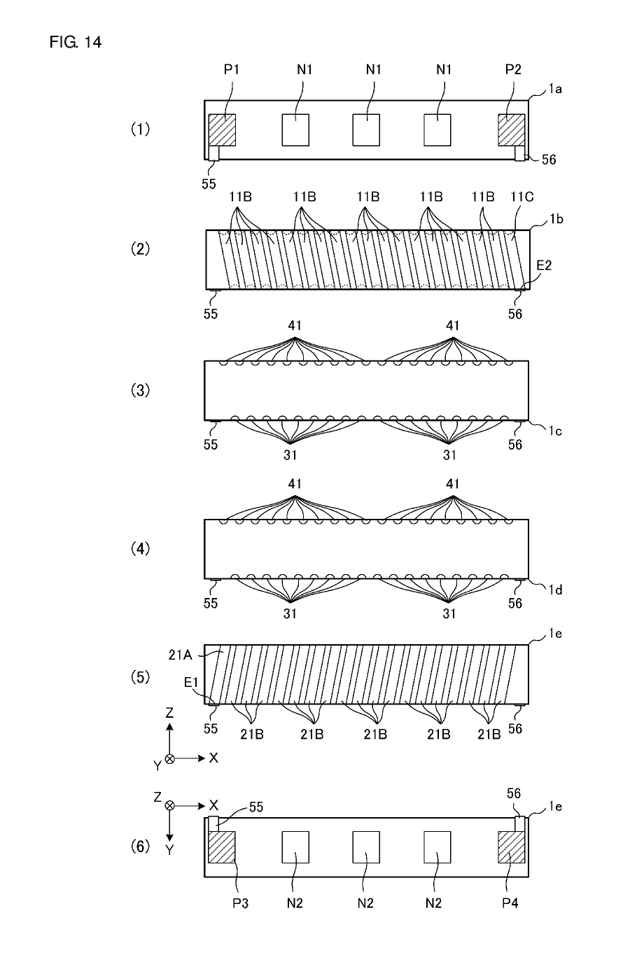

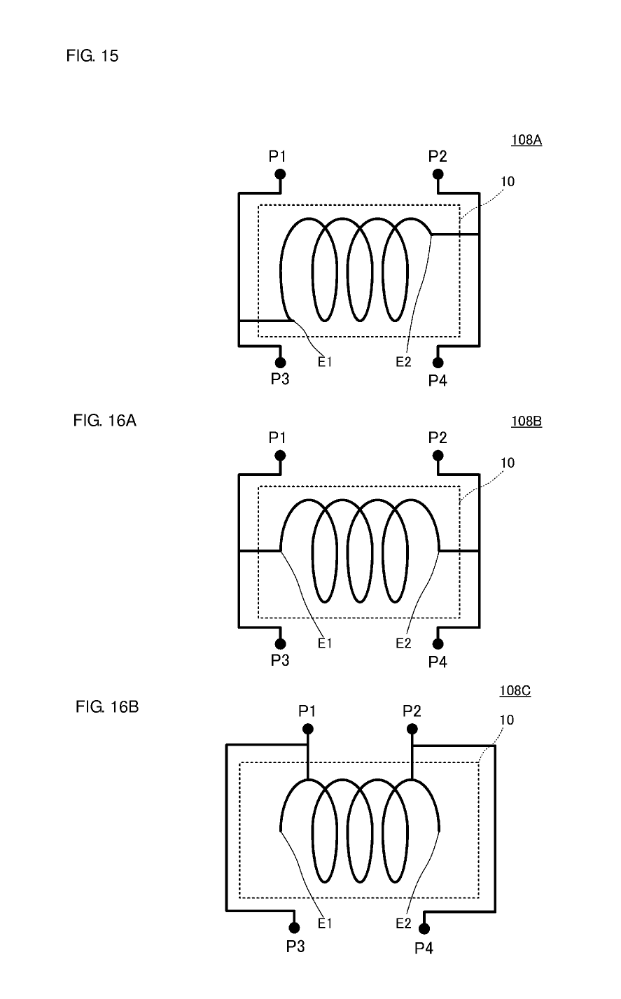

FIG. 14 is an exploded plan view illustrating electrode patterns, etc. on individual base material layers of a coil antenna 108A according to an eighth preferred embodiment of the present invention. FIG. 15 is a circuit diagram of the coil antenna 108A. FIG. 16A is a circuit diagram of a coil antenna 108B according to the eighth preferred embodiment, and FIG. 16B is a circuit diagram of a coil antenna 108C.

The coil antennas 108A, 108B, and 108C are different from the coil antenna 101 according to the first preferred embodiment in that the first pad electrode P1 and the third pad electrode P3 are electrically connected to each other at the surface of the insulator 10. The coil antennas 108A, 108B, and 108C are further different from the coil antenna 101 in that the second pad electrode P2 and the fourth pad electrode P4 are electrically connected at the surface of the insulator 10. The other configuration is substantially the same as that of the coil antenna 101.

The coil antenna 108A includes conductor patterns 55 and 56 provided at the surface of the insulator 10. The conductor pattern 55 preferably extends over the first principal surface, the second principal surface, and the first lateral surface of the insulator 10 for electrical connection between the first pad electrode P1 and the third pad electrode P3. In this preferred embodiment, the conductor pattern 55 corresponds to both a first connection conductor and a third connection conductor.

The conductor pattern 56 is defined to extend over the first principal surface, the second principal surface, and the first lateral surface of the insulator 10 for electrical connection between the second pad electrode P2 and the fourth pad electrode P4. In this preferred embodiment, the conductor pattern 56 corresponds to both a second connection conductor and a fourth connection conductor.

Unlike the coil antenna 101 according to the first preferred embodiment, the coil antenna 108A preferably has neither the first linear conductor having the trapezoidal shape in a plan view, nor the second linear conductor having the trapezoidal shape in a plan view. Therefore, the coil antenna 108A has the end portion E1 positioned at a lower side of the second linear conductor 21A, which faces (reaches) one side of the base material layer 1e in the widthwise direction (i.e., the lower side of the base material layer 1e in FIG. 14). As illustrated in FIG. 14, the conductor pattern 55 is electrically connected to the end portion E1, whereby the first pad electrode P1 and the third pad electrode are connected to the first end portion side (i.e., the end portion E1).

Furthermore, the coil antenna 108A has the end portion E2 positioned at a lower side of the first linear conductor 11C, which faces (reaches) one side of the base material layer 1b in the widthwise direction (i.e., the lower side of the base material layer 1e in FIG. 14). As illustrated in FIG. 14, the conductor pattern 56 is electrically connected to the end portion E2, and the second pad electrode P2 and the fourth pad electrode are connected to the second end portion side (i.e., the end portion E2).

With such a configuration, the coil conductor and the pad electrode are able to be electrically connected to each other without using the interlayer connection conductor. Accordingly, there is no need of forming vias in the base material layers 1a and 1e, and filling a conductive paste into the vias.

In the coil antenna 108A according to this preferred embodiment, when a conductive bonding material, such as a solder, is used for connection, there is a possibility that the conductive bonding material may spread out over the conductor patterns 55 and 56 and the coil conductor. For that reason, plating films used in mounting are preferably provided only on the pad electrodes.

Moreover, with the configuration described above, a coil antenna exhibiting good communication characteristics is able to be realized because the first pad electrode P1, the second pad electrode P2, the third pad electrode P3, the fourth pad electrode P4, and the conductor patterns 55 and 56 (i.e., the first connection conductor, the second connection conductor, the third connection conductor, and the fourth connection conductor) do not impede magnetic flux passing through the coil aperture.

Moreover, in the coil antenna 108B, as illustrated in FIG. 16A, the first pad electrode P1 and the third pad electrode P3 are electrically connected to each other through the conductor pattern provided at the surface of the insulator 10, and the relevant conductor pattern is connected to the first end side (vicinity of the end portion E1) of the coil conductor. The second pad electrode P2 and the fourth pad electrode P4 are electrically connected to each other through the conductor pattern provided at the surface of the insulator 10, and the relevant conductor pattern is connected to the second end side (vicinity of the end portion E2) of the coil conductor.

Stated in another way, the first pad electrode P1 and the third pad electrode P3 are both electrically connected to the same position on the first end side, and the second pad electrode P2 and the fourth pad electrode P4 are both electrically connected to the same position on the second end side.

In the coil antenna 108C, as illustrated in FIG. 16B, the first pad electrode P1 is connected to the first end side (vicinity of the end portion E1) of the coil conductor, and the second pad electrode P2 is connected to the second end side (vicinity of the end portion E2) of the coil conductor. The third pad electrode P3 is branched from a point between the first end side of the coil conductor and the first pad electrode P1 at the surface of the insulator 10. In other words, the third pad electrode P3 is electrically connected to the first pad electrode P1 through the conductor pattern provided at the surface of the insulator 10. The fourth pad electrode P4 is branched from a point between the second end side of the coil conductor and the second pad electrode P2 at the surface of the insulator 10. In other words, the fourth pad electrode P4 is electrically connected to the second pad electrode P2 through the conductor pattern provided at the surface of the insulator 10.

Accordingly, in the coil antenna 108C, the first pad electrode P1 and the third pad electrode P3 are both electrically connected to the same position on the first end side, and the second pad electrode P2 and the fourth pad electrode P4 are both electrically connected to the same position on the second end side.

The thus-defined coil antennas 108A, 108B, and 108C according to this preferred embodiment also have the same basic configuration as the coil antenna 101 according to the first preferred embodiment, and ensure similar operation and advantageous effects to those in the coil antenna 101.

Furthermore, in each of the coil antennas 108A, 108B, and 108C according to this preferred embodiment, the first pad electrode P1 and the third pad electrode P3 are both electrically connected to the same position on the first end side, and the second pad electrode P2 and the fourth pad electrode P4 are both electrically connected to the same position on the second end side. Therefore, an inductance component between the first pad electrode P1 and the second pad electrode P2 is equal to that between the third pad electrode P3 and the fourth pad electrode P4. As a result, a coil antenna is realized in which the inductance component is always held constant even when the coil antenna is connected using any of various connection methods.

While the coil antenna 108C according to this preferred embodiment has been described in relation to an example in which the third pad electrode P3 is branched from the point between the first end side of the coil conductor and the first pad electrode P1 at the surface of the insulator 10, and the fourth pad electrode P4 is electrically connected to the second pad electrode P2 at the surface of the insulator 10, the present invention is not limited to such an example. In another example, the first pad electrode P1 may be branched from a point between the first end side of the coil conductor and the third pad electrode P3 at the surface of the insulator 10, and the second pad electrode P2 may be electrically connected to the fourth pad electrode P4 at the surface of the insulator 10

### Ninth Preferred Embodiment

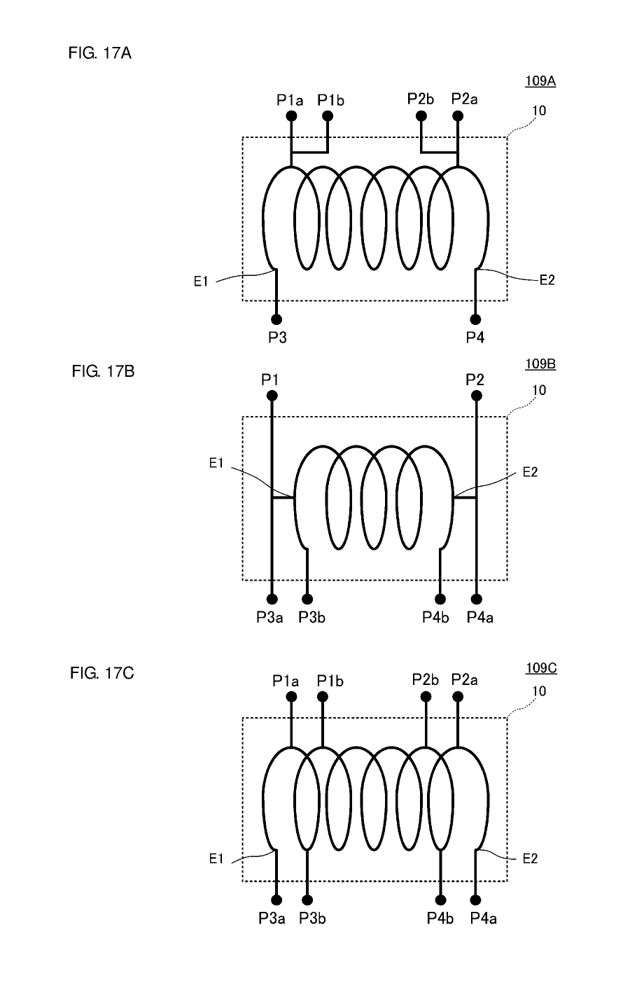

FIG. 17A is a circuit diagram of a coil antenna 109A according to a ninth preferred embodiment of the present invention, FIG. 17B is a circuit diagram of a coil antenna 109B, and FIG. 17C is a circuit diagram of a coil antenna 109C.

The coil antennas 109A, 109B, and 109C are preferably different from the coil antenna 101 according to the first preferred embodiment in including a plurality of electrodes per pad electrode. The other configuration is preferably substantially the same as that of the coil antenna 101.

The coil antenna 109A includes two first pad electrodes P1a and P1b, and two second pad electrodes P2a and P2b. The two first pad electrodes P1a and P1b are both connected to the first end side (vicinity of the end portion E1) of the coil conductor, and the third pad electrode P3 is connected to the first end (end portion E1) of the coil conductor. The two second pad electrodes P2a and P2b are both connected to the second end side (vicinity of the end portion E2) of the coil conductor, and the fourth pad electrode P4 is connected to the second end (end portion E2) of the coil conductor.

In other words, the two first pad electrodes P1a and P1b are both electrically connected to the same position on the first end side, and the two second pad electrodes P2a and P2b are both electrically connected to the same position on the second end side.

With the configuration described above, in the coil antenna 109A, inductance components are equal between the first pad electrode P1a and the second pad electrode P2a, between the first pad electrode P1a and the second pad electrode P2b, between the first pad electrode P1b and the second pad electrode P2a, and between the first pad electrode P1b and the second pad electrode P2b. As a result, a coil antenna is realized which is adaptable for various connection methods while the inductance component is held constant or substantially constant.

The coil antenna 109B includes two third pad electrodes P3a and P3b, and two fourth pad electrodes P4a and P4b. The third pad electrode P3a and the first pad electrode P1 are connected to the first end side (vicinity of the end portion E1) of the coil conductor, and the third pad electrode P3b is connected to the first end (end portion E1) of the coil conductor. The fourth pad electrode P4a and the second pad electrode P2 are connected to the second end side (vicinity of the end portion E2) of the coil conductor, and the fourth pad electrode P4b is connected to the second end (end portion E2) of the coil conductor.

With the configuration described above, an inductance component between the first pad electrode P1a and the second pad electrode P2 is equal or substantially equal to that between the third pad electrode P3a and the fourth pad electrode P4a. As a result, a coil antenna is realized in which the inductance component is always held constant even when the coil antenna is connected using any of various connection methods.

Furthermore, with the configuration described above, inductance components between the first pad electrode P1 and the fourth pad electrode P4b, between the second pad electrode P2 and the third pad electrode P3b, between the third pad electrode P3a and the fourth pad electrode P4b, between the third pad electrode P3b and the fourth pad electrode P4a, and between the third pad electrode P3b and the fourth pad electrode P4b are different from those between the first pad electrode P1 and the second pad electrode P2 and between the third pad electrode P3a and the fourth pad electrode P4a.

As a result, a coil antenna is realized which is adaptable for various connection methods, and which allows the inductance component to be selected optionally.

The coil antenna 109C includes two first pad electrodes P1a and P1b, two second pad electrodes P2a and P2b, two third pad electrodes P3a and P3b, and two fourth pad electrodes P4a and P4b. As illustrated in FIG. 17C, the first pad electrodes P1a and P1b and the third pad electrodes P3a and P3b are electrically connected to different positions on the first end side. The second pad electrodes P2a and P2b and the fourth pad electrodes P4a and P4b are electrically connected to different positions on the second end side.

As represented by this preferred embodiment, by changing the number of electrodes per pad electrode, a coil antenna is able to be realized which is adaptable for a more variety of connection methods, and which allows the inductance component to be selected optionally from a wider range.

### Tenth Preferred Embodiment

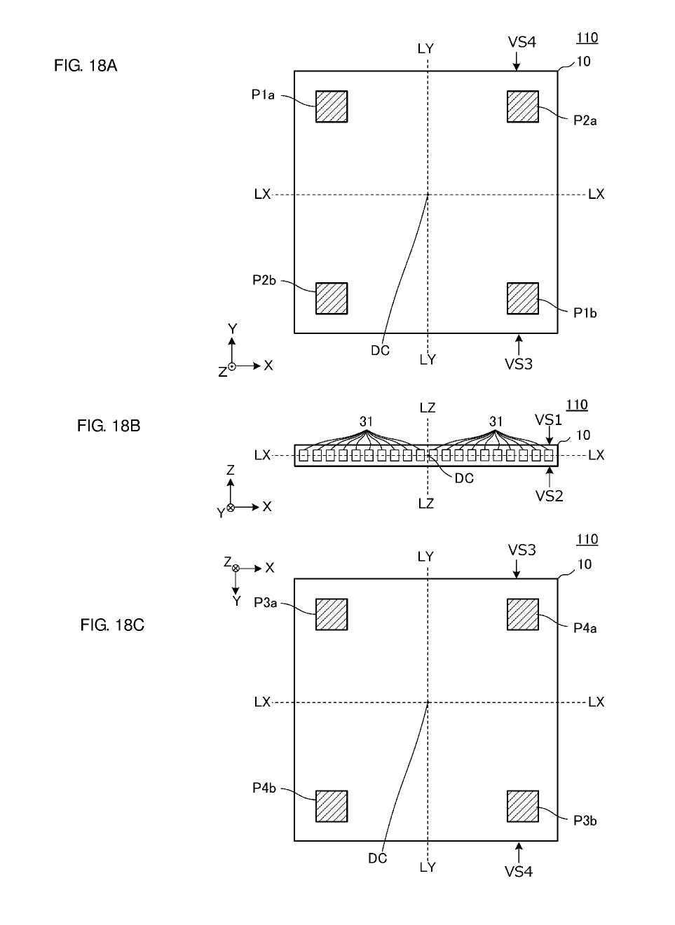

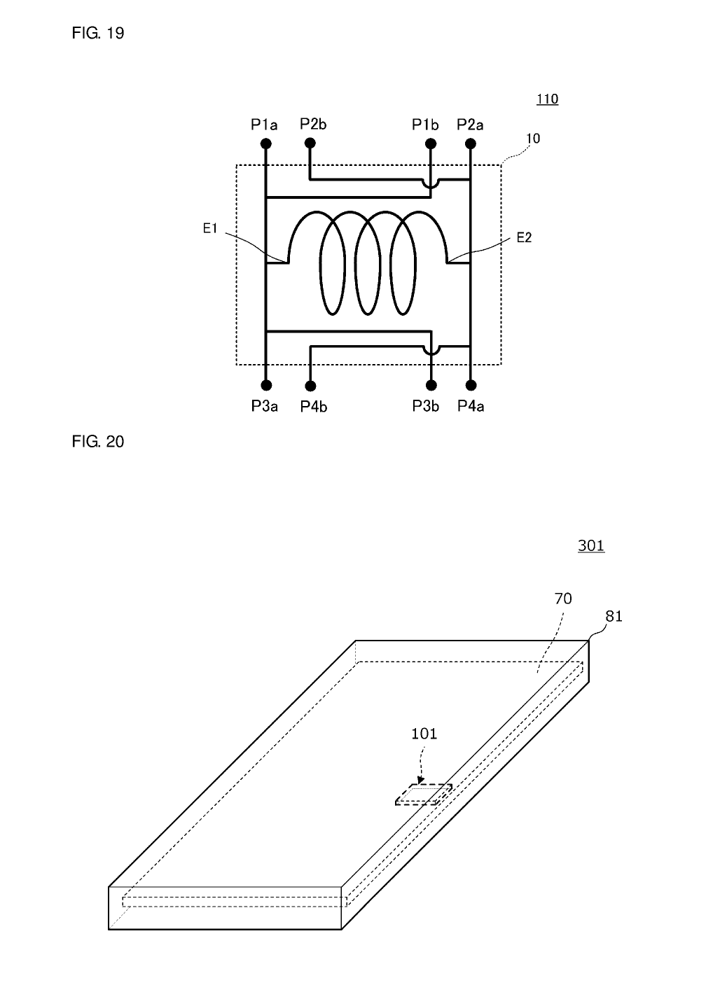

FIG. 18A is a plan view of a coil antenna 110 according to a tenth preferred embodiment of the present invention, FIG. 18B is a front view of the coil antenna 110, and FIG. 18C is a bottom view of the coil antenna 110. FIG. 19 is a circuit diagram of the coil antenna 110.

The coil antenna 110 is preferably different from the coil antenna 102 in including four pad electrodes at the first principal surface of the insulator 10 and four pad electrodes at the second principal surface of the insulator 10. The other configuration is preferably substantially the same as that of the coil antenna 102.

As illustrated in FIG. 18A, the coil antenna 110 includes two first pad electrodes P1a and P1b and two second pad electrodes P2a and P2b at the first principal surface of the insulator 10, and two third pad electrodes P3a and P3b and two fourth pad electrodes P4a and P4b at the second principal surface of the insulator 10.

The two first pad electrodes P1a and P1b are both connected to the first end side (end portion E1) of the coil conductor, and the two third pad electrodes P3a and P3b are also both connected to the first end (end portion E1) of the coil conductor. The two second pad electrodes P2a and P2b are both connected to the second end side (end portion E2) of the coil conductor, and the two fourth pad electrodes P4a and P4b are also both connected to the second end (end portion E2) of the coil conductor.

Thus, the two first pad electrodes P1a and P1b and the two third pad electrodes P3a and P3b are all electrically connected to the same position on the first end side, and the two second pad electrodes P2a and P2b and the two fourth pad electrodes P4a and P4b are all electrically connected to the same position on the second end side.

The first pad electrodes P1a and P1b are arranged, when looking at the first principal surface, respectively near a first corner of the insulator 10 (upper left corner of the insulator 10 in FIG. 18A) and near a second corner thereof (lower right corner of the insulator 10 in FIG. 18A). The second pad electrodes P2a and P2b are arranged, when looking at the first principal surface, respectively near a third corner of the insulator 10 (upper right corner of the insulator 10 in FIG. 18A) and near a fourth corner thereof (lower left corner of the insulator 10 in FIG. 18A).

Stated in another way, the first pad electrodes P1a and P1b and the second pad electrodes P2a and P2b, which are provided at the first principal surface of the insulator 10, are arranged in such a structure that one of two adjacent pad electrodes among them is connected to the first end side of the coil conductor and the other is connected to the second end side of the coil conductor. Thus, the pad electrodes arranged in a 180° rotational symmetrical relationship about the Z axis passing the center DC of the insulator 10 are connected to the same end portion side of the coil conductor. In the above structure, the adjacent pad electrodes are preferably arranged in a 90° rotational symmetrical relationship about the Z axis passing the center DC of the insulator 10.

Moreover, the third pad electrodes P3a and P3b are arranged, when looking at the second principal surface, respectively near a first corner of the insulator 10 (upper left corner of the insulator 10 in FIG. 18C) and near a second corner thereof (lower right corner of the insulator 10 in FIG. 18C). The fourth pad electrodes P4a and P4b are arranged, when looking at the second principal surface, respectively near a third corner of the insulator 10 (upper right corner of the insulator 10 in FIG. 18C) and near a fourth corner thereof (lower left corner of the insulator 10 in FIG. 18C).

Stated in another way, the third pad electrodes P3a and P3b and the fourth pad electrodes P4a and P4b, which are provided at the second principal surface of the insulator 10, are arranged in such a structure that one of two adjacent pad electrodes among them is connected to the first end side of the coil conductor and the other is connected to the second end side of the coil conductor. Thus, the pad electrodes arranged in a 180° rotational symmetrical relationship about the Z axis passing the center DC of the insulator 10 are connected to the same end portion side of the coil conductor. In the above structure, the adjacent pad electrodes are arranged in a 90° rotational symmetrical relationship about the Z axis passing the center DC of the insulator 10.

With the configuration described above, even when the coil antenna 110 is rotated by 90° with respect to the Z axis passing the center DC of the insulator 10, the pad electrodes electrically connected to the coil conductor remain in the same positional relationship relative to one another. In other words, as represented by this preferred embodiment, the layout of the first pad electrode and the second pad electrode when looking at the first principal surface (or the third pad electrode and the fourth pad electrode when looking at the second principal surface) is not limited to a point symmetrical relationship (i.e., a 180° rotational symmetrical relationship) with respect to the center DC of the insulator 10.

Thus, the layout of the first pad electrode and the second pad electrode when looking at the first principal surface (or of the third pad electrode and the fourth pad electrode when looking at the second principal surface) may be in a 360°/n-folded point symmetrical relationship (n is an integer of 2 or more) with respect to the center DC of the insulator 10.

In a coil antenna or the like that radiates magnetic flux to the outside, however, if a rotation axis of rotational symmetry is not the same as the winding axis of the coil conductor, the direction of the winding axis of the coil conductor is changed with rotation of the coil antenna or the like, and radiation characteristics of the coil antenna is changed significantly. For that reason, in the coil antenna or the like, when the rotation axis of rotational symmetry is not the same as the winding axis of the coil conductor, the pad electrodes are preferably arranged to have 180° rotational symmetry.

### Eleventh Preferred Embodiment

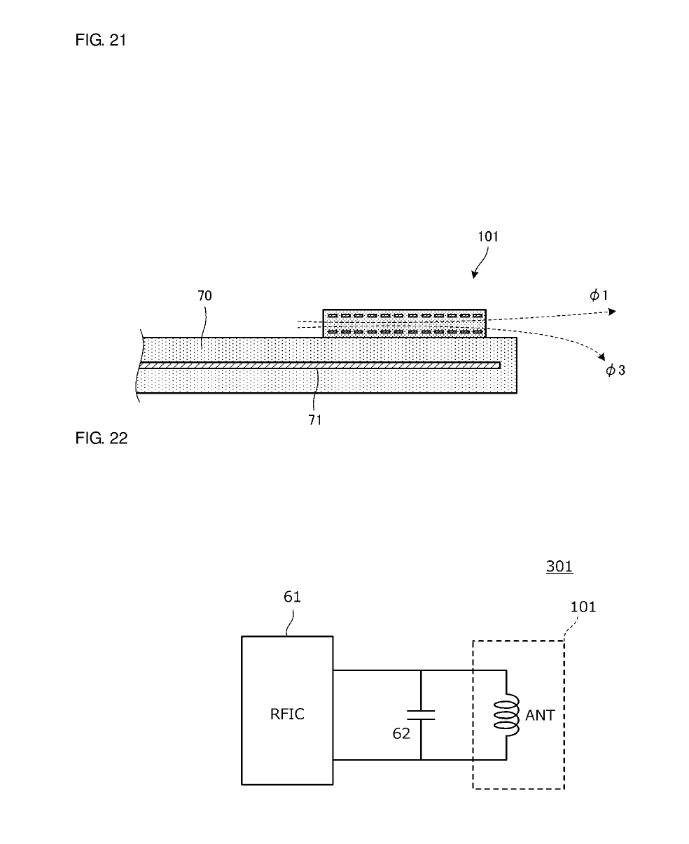

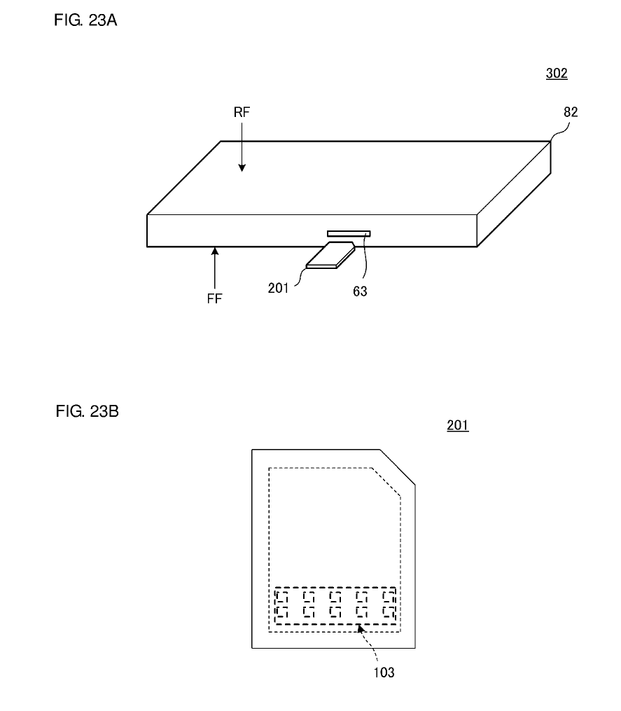

FIG. 20 is an external perspective view of an electronic device 301 according to an eleventh preferred embodiment of the present invention. FIG. 21 is a partial sectional view of the electronic device 301, the view illustrating a path of interlinkage magnetic flux with respect to the coil antenna 101 mounted on a wiring board 70. FIG. 22 is a circuit diagram of a communication circuit in the electronic device 301.

The electronic device 301 is preferably, for example, a cellular phone terminal (including a smartphone or a feature phone), a wearable terminal (such as a smart watch or a smart glass), a notebook computer, a tablet terminal, a PDA, a camera, a game machine, a toy, and an information medium such as an RFID tag, an IC tag, an SD (registered trademark) (Secure Digital) card, a SIM card, or an IC card.

The electronic device 301 includes the coil antenna 101, a wiring board 70 including a ground conductor 71 embedded therein, and a casing 81.

The coil antenna 101 and the wiring board 70 are accommodated in the casing 81, and the coil antenna 101 is mounted to the wiring board 70. The wiring board 70 is, for example, a printed wiring board.

As illustrated in FIGS. 20 and 21, the coil antenna 101 is mounted to one principal surface (upper surface in FIG. 20) of the wiring board 70 including the ground conductor 71 embedded therein, and it is arranged near an edge portion of the wiring board 70. The ground conductor 71 extends over substantially the entirety of the wiring board 70. Thus, the coil antenna 101 is arranged near an edge portion of the ground conductor 71.

With the configuration described above, when a current flows through the coil conductor of the coil antenna 101, magnetic flux φ1 is generated to propagate along the direction of the winding axis of the coil conductor. Moreover, magnetic flux φ3 is generated to propagate while curving toward the mounting surface (lower surface in FIG. 21) of the coil antenna 101. Thus, with the coil antenna 101 arranged near the edge portion of the wiring board 70, the magnetic flux is able to be caused to spread downward of the wiring board 70 without being blocked off by the ground conductor 71 in the wiring board 70. In addition, the coil antenna 101 and the edge portion of the ground conductor 71 are magnetically coupled to each other via a portion of the magnetic flux φ3, thus generating an induction current that circulates through the edge portion of the ground conductor 71. Hence the ground conductor 71 defines and functions also as a booster antenna that radiates magnetic flux.

While the above description is made in relation to an example in which the ground conductor 71 defines and functions as a radiator that radiates magnetic flux in the case where the coil antenna 101 is an antenna on the transmitting side, the ground conductor 71 acts as a collector that collects magnetic flux in the case where the coil antenna 101 is an antenna on the receiving side. In other words, the coil antenna 101 operates in a similar manner also when it is used as the antenna on the receiving side.

Thus, even with an electronic device not including a radio communication system, the electronic device can be adaptable for a communication system in an HF band or a UHF band with the provision of the coil antenna 101 according to a preferred embodiment of the present invention. Accordingly, data can be transmitted to and received from an external electronic device or another external device with NFC (Near Field Communication) through magnetic field coupling.

Inside the electronic device 301, a circuit illustrated in FIG. 22 is defined as a communication circuit. As illustrated in FIG. 22, a coil conductor ANT of the coil antenna 101 is connected to an RFIC element 61, and a chip capacitor 62 is connected in parallel to the coil conductor. An LC resonant circuit is defined by the coil conductor ANT, the chip capacitor 62, and a capacitance component of the RFIC element 61 itself. A capacitance of the chip capacitor 62 is selected so as to make the resonant frequency of the LC resonant circuit become a frequency (e.g., 13.56 MHz) that is equal or substantially equal to the communication frequency of the RFID system.

### Twelfth Preferred Embodiment

FIG. 23A is an external perspective view of an electronic device 302 according to a twelfth preferred embodiment of the present invention, and FIG. 23B is a plan view of a card information medium 201 according to the twelfth preferred embodiment.

A casing 82 of the electronic device 302 is a rectangular or substantially rectangular parallelepiped casing having a lengthwise direction and a widthwise direction. The casing 82 includes a front surface FF (one principal surface), a rear surface RF (the other principal surface), and four lateral surfaces interconnecting the front surface FF and the rear surface RF. The casing 82 may be of the type defined by connecting two casings to each other, like a slide terminal or a clam shell (folded) terminal, a bar, for example.

The casing 82 of the electronic device 302 includes a card slot 63 into and from which a card information medium 201 is inserted and withdrawn.

A not-illustrated RFIC element and the coil antenna 103 are disposed inside the card information medium 201. A plurality of electrodes is exposed at a lower surface of the card information medium 201 in FIG. 23B.

The card information medium 201 is preferably, for example, a small-sized card device capable of being mounted to or removed from a terminal unit body, like a memory card such as an SD (registered trademark) (Secure Digital) card, or an SIM (Subscriber Identity Module). The card information medium 201 includes the coil antenna 103 that is connected to the RFIC element.

A slot case is mounted to a wiring board that is disposed inside the casing 82. The slot case constitutes a space (slot) that is defined between the slot case and the wiring board, and that allows the card information medium 201 to be inserted into and removed from it.

Terminals with which the plurality of electrodes exposed at the lower surface of the card information medium 201 are brought into contact for electrical conduction are disposed at a surface of the wiring board, the surface being opposed to the slot case. By inserting the card information medium 201 into the card slot 63, the card information medium 201 is loaded into the slot case such that the electrodes of the card information medium 201 are electrically connected to the terminals of the wiring board for electrical conduction to a power feed circuit.

Thus, even with an electronic device not including a radio communication system, the electronic device is adaptable for a communication system in an HF band or a UHF band by inserting the card information medium 201, which includes the coil antenna 103 according to a preferred embodiment of the present invention, into the card slot 63 of the electronic device. Accordingly, data can be transmitted to and received from an external electronic device or another external device with NFC (Near Field Communication) through magnetic field coupling.

### Thirteenth Preferred Embodiment

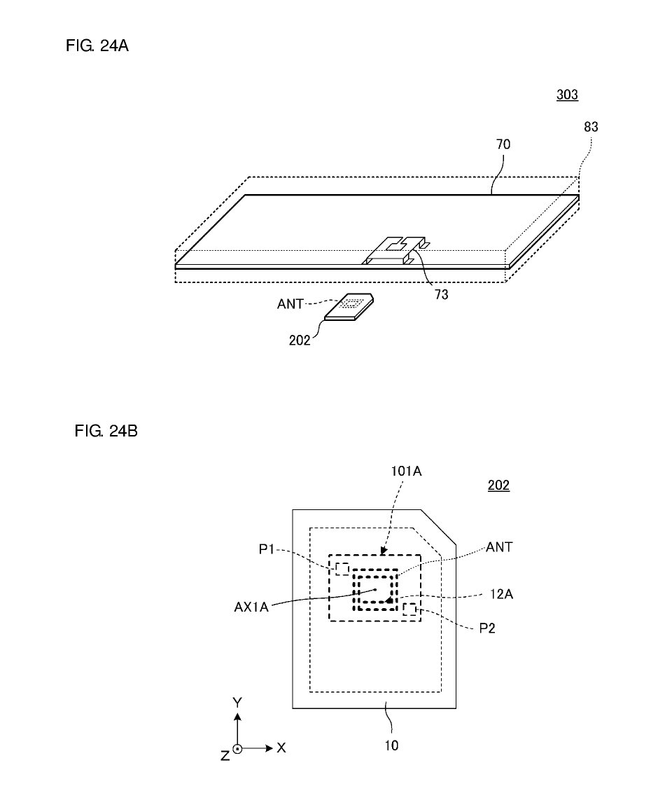

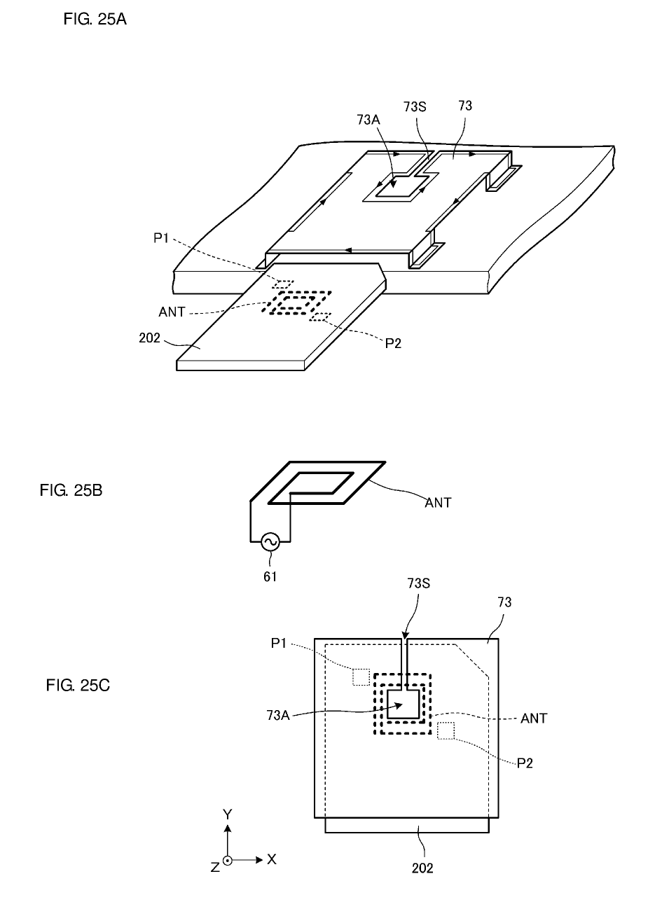

FIG. 24A is an external perspective view of an electronic device 303 according to a thirteenth preferred embodiment of the present invention, and FIG. 24B is a plan view of a card information medium 202 according to the thirteenth preferred embodiment. It is to be noted that a casing 83 is not illustrated in FIG. 24A. FIG. 25A is a perspective view of a portion of a wiring board 70 where a slot case 73 is mounted to the wiring board 70, FIG. 25B illustrates a shape of a coil conductor ANT, and FIG. 25C illustrates a relationship between the slot case 73 and the coil conductor ANT in a plan view.

The electronic device 303 preferably includes the card information medium 202, a casing 83, the wiring board 70, and the slot case 73. The casing 83 of the electronic device 303 includes a card slot (not illustrated) into and from which the card information medium 202 is inserted and withdrawn. The card information medium 202, the wiring board 70, and the slot case 73 are accommodated in the casing 83, and the slot case 73 is mounted to the wiring board 70.

A not-illustrated RFIC element and a coil antenna 101A are preferably disposed inside the card information medium 202. The coil antenna 101A includes an insulator 10, the coil conductor ANT, a first pad electrode P1, a second pad electrode P2, a third pad electrode, and a fourth pad electrode (the last two being not illustrated). The coil conductor ANT of the coil antenna 101A is different from that of the coil antenna 101 according to the first preferred embodiment in having a winding axis AX1A that is parallel to a thickness direction (Z direction in FIG. 24B).

A plurality of electrodes is exposed at a lower surface of the card information medium 202 in FIG. 24B for electrical connection to the third pad electrode and the fourth pad electrode of the coil antenna 101A.

The slot case 73 is mounted to the wiring board 70 that is disposed inside the casing 83. The slot case 73 corresponds to a “card loading assembly” into and from which the card information medium according to a preferred embodiment of the present invention can be inserted and removed. The slot case 73 defines a space (slot) that is defined between the slot case and the wiring board 70, and that allows the card information medium 202 to be inserted into and removed from it.

Terminals with which the plurality of electrodes exposed at the lower surface of the card information medium 202 are brought into contact for electrical conduction are disposed at a surface of the wiring board 70, the surface being opposed to the slot case 73. By inserting the card information medium 202 into the card slot, the card information medium 202 is loaded into the slot case 73 such that the electrodes of the card information medium 202 are electrically connected to the terminals of the wiring board for electrical conduction to a power feed circuit. Thus, the third pad electrode and the fourth pad electrode are electrically conducted to the power feed circuit.

The slot case 73 is preferably defined by a metal member made of stainless steel, for example, or it is at least partly made of a metal member. A metal portion of the slot case 73 includes an opening 73A that is provided at a position facing a coil aperture of the coil conductor ANT, and a slit 73S that interconnects the opening 73A and an outer edge of the slot case 73.

As illustrated in FIG. 25B, the coil conductor ANT is preferably a spiral coil having a rectangular or substantially rectangular shape, and the RFIC element 61 is connected to both ends of the coil conductor ANT. Since the opening 73A of the slot case 73 is provided at the position facing the coil aperture of the coil conductor ANT, the coil conductor ANT is positioned close to the slot case 73 when the card information medium 202 is loaded into the slot case 73. Accordingly, the slot case 73 is coupled to the coil conductor through an electric field, a magnetic field, or an electromagnetic field.

Furthermore, since the slot case 73 is disposed in a region opposing to both the first pad electrode P1 and the second pad electrode P2 of the coil antenna 101A, the first pad electrode P1 and the second pad electrode P2 are positioned close to the slot case 73 when the card information medium 202 is loaded into the slot case 73. Accordingly, the slot case 73 is coupled to the first pad electrode P1 and the second pad electrode P2 through an electric field.

Thus, in the state where the slot case 73 is coupled to the first pad electrode P1 and the second pad electrode P2 or to the coil conductor ANT through an electric field, a magnetic field, or an electromagnetic field, a current flows in the slot case 73 while going around the opening 73A as denoted by arrows in FIG. 25A. However, since the slit 73S interconnecting the opening 73A and the outer edge of the slot case 73 is formed in the slot case 73, the current is caused to flow along the outer edge of the slot case 73 via a region including the slot 73S, whereas an eddy current does not flow in the slot case 73.

In such a manner, the slot case 73 defines and functions as a booster antenna of the coil antenna 101A. Accordingly, an electronic device is realized in which the slot case 73 does not impede passage of the magnetic flux, and which enables the coil antenna 101A included in the card information medium 202 to be strongly coupled to a coil antenna on the communication counterpart side.

### Fourteenth Preferred Embodiment

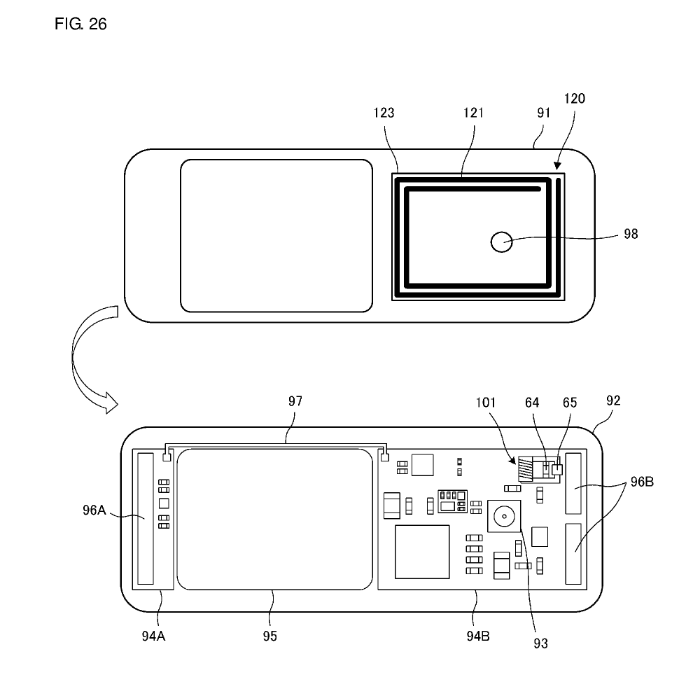

FIG. 26 is a plan view illustrating a structure inside a casing of an electronic device according to a fourteenth preferred embodiment of the present invention.

The electronic device according to the fourteenth preferred embodiment includes the coil antenna 101 and a booster antenna 120 having a resonant frequency.

A camera module 93, circuit boards 94A and 94B, a battery pack 95, etc. are preferably accommodated inside an upper casing 92. A UHF-band antenna 96A, etc. are mounted to the circuit board 94A. The circuit boards 94A and 94B are connected to each other through a coaxial cable 97. Furthermore, a UHF-band antenna 96B, a power feed circuit 65 including a communication circuit, a surface mount component 64, and the coil antenna 101 connected to the power feed circuit 65 are preferably mounted to the circuit board 94B. The power feed circuit 65 is electromagnetically coupled to the booster antenna 120 via the coil conductor of the coil antenna 101. The surface mount component 64 is, for example, a chip capacitor of a resonant circuit.

The booster antenna 120 is bonded to an inner surface of a lower casing 91. The booster antenna 120 includes a hole 98 for a camera. The booster antenna 120 is arranged at a position not overlapping the battery pack 95.

The coil antenna 101 is arranged in an interlinkage relationship to magnetic flux passing the booster antenna 120. In other words, the coil conductor of the coil antenna 101 is preferably arranged to be magnetically coupled to a coil of the booster antenna 120.

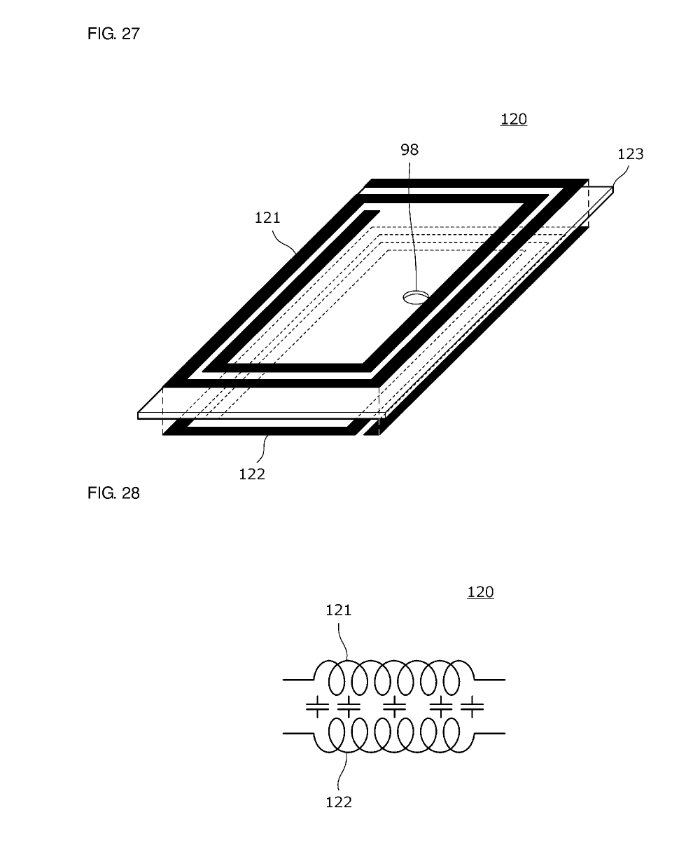

FIG. 27 is a perspective view of the booster antenna 120. FIG. 28 is a circuit diagram of the booster antenna 120.

The booster antenna 120 includes an insulator base 123 and coil patterns 121 and 122 that are provided on or in the insulator base 123. In the booster antenna 120, the first coil pattern 121 and the second coil pattern 122 are conductors each patterned into a rectangular or substantially rectangular spiral shape such that both the coil patterns are capacitively coupled to each other in a state where currents flow in the same direction when seen in a plan view. A capacitance (electrostatic capacitance) is generated between the first coil pattern 121 and the second coil pattern 122. An LC resonant circuit is defined by respective inductances of the first coil pattern 121 and the second coil pattern 122 and the capacitance generated between them. A resonant frequency of the LC resonant circuit is equal or substantially equal to a communication frequency of the RFID system. The communication frequency is preferably, for example, a band of 13.56 MHz.

According to this preferred embodiment, since communication is able to be performed by utilizing a large coil aperture of the booster antenna, a communicable maximum distance is able to be increased.

### Other Preferred Embodiments

While the above preferred embodiments of the present invention have been described in relation to examples in which the electronic devices preferably have rectangular or substantially rectangular parallelepiped shapes, the present invention is not limited to such examples. The electronic devices may be modified as appropriate to have a cubic shape, a polygonal shape, a circular cylindrical shape, or an elliptical columnar shape, for example.

While the above preferred embodiments have been described mainly in relation to the antenna devices and the electronic devices in a communication system utilizing magnetic field coupling, such as NFC, the antenna devices and the electronic devices in the above preferred embodiments can also be similarly used in a noncontact power transfer system (electromagnetic induction type or magnetic resonance type) utilizing magnetic field coupling, for example. The antenna devices in the above preferred embodiments can be each used as a power receiving antenna unit of a power receiving device or a power transmitting antenna unit of a power transmitting device in the noncontact power transfer system of magnetic resonance type, which is preferably used, for example, at a frequency in an HF band (particularly, 6.78 MHz or near 6.78 MHz). The antenna device is connected to a power feed circuit (power receiving circuit) that supplies electric power to a load (such as a secondary battery) that is equipped in the power receiving device. Also in the above case, the antenna device defines and functions as the power receiving device or the power transmitting device. Both ends of the coil conductor of the antenna device are connected to a power receiving circuit or a power transmitting circuit, which preferably uses the use frequency band (HF band, particularly 6.78 MHz or near 6.78 MHz).

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An inductor element comprising:
an insulator that includes a first principal surface and a second principal surface opposing to the first principal surface;
a coil conductor that is provided on or in the insulator, that has a winding axis, and that includes a first end and a second end;
a first pad electrode that is provided at the first principal surface, and that is electrically connected to the first end side;
a second pad electrode that is provided at the first principal surface, and that is electrically connected to the second end side;
a third pad electrode that is provided at the second principal surface, and that is electrically connected to a position different from a connected position of the first pad electrode on the second end side; and
a fourth pad electrode that is provided at the second principal surface, and that is electrically connected to a position different from a connected position of the second pad electrode on the second end side; wherein
the first pad electrode, the second pad electrode, the third pad electrode, and the fourth pad electrode are independent of one another; and
an inductance component between the first pad electrode and the second pad electrode is different from an inductance component between the second pad electrode and the third pad electrode.

2. The inductor element according to claim 1, wherein an inductance component between the first pad electrode and the second pad electrode is different from an inductance component between the first pad electrode and the fourth pad electrode.

3. The inductor element according to claim 1, wherein an inductance component between the first pad electrode and the second pad electrode is different from an inductance component between the third pad electrode and the fourth pad electrode.

4. The inductor element according to claim 1, wherein
the first principal surface includes a first side and a second side perpendicular to the first side; and
the insulator is a rectangular or substantially rectangular parallelepiped including a third side that is perpendicular to the first side and the second side.

5. The inductor element according to claim 4, wherein
the first pad electrode and the third pad electrode are rotationally symmetrical about a first axis that passes a center of the insulator, and that is parallel to the first side; and
the second pad electrode and the fourth pad electrode are rotationally symmetrical about the first axis that passes the center of the insulator, and that is parallel to the first side.

6. The inductor element according to claim 4, wherein
the first pad electrode and the fourth pad electrode are rotationally symmetrical about a second axis that passes a center of the insulator, and that is parallel to the second side; and
the second pad electrode and the third pad electrode are rotationally symmetrical about the second axis that passes the center of the insulator, and that is parallel to the second side.

7. The inductor element according to claim 4, wherein
the first pad electrode and the second pad electrode are rotationally symmetrical about a third axis that passes a center of the insulator, and that is parallel to the third side; and
the third pad electrode and the fourth pad electrode are rotationally symmetrical about the third axis that passes the center of the insulator, and that is parallel to the third side.

8. The inductor element according to claim 1, wherein
the coil conductor includes first linear conductors, second linear conductors, first connection conductors, and second connection conductors; and
the first linear conductors and the second linear conductors are provided in parallel with the first principal surface and the second principal surface.
